(19) United States
(12) Patent Application Publication
(10) Pub. No.: US 2025/0372179 A1
(43) Pub. Date: Dec. 4, 2025

(54) MEMORY SYSTEMS, OPERATION METHODS THEREOF, AND COMPUTER READABLE STORAGE MEDIA

(71) Applicant: Yangtze Memory Technologies Co., Ltd., Wuhan (CN)

(72) Inventor: Teng Zhou, Wuhan (CN)

(21) Appl. No.: 18/822,074

(22) Filed: Aug. 30, 2024

(30) Foreign Application Priority Data
Jun. 3, 2024 (CN) 2024107121570

(51) Int. Cl. G11C 16/26; G11C 16/32; G11C 16/34

(52) U.S. Cl. CPC G11C 16/26; G11C 16/32; G11C 16/3418

(57) ABSTRACT

The implementations of the present disclosure provide memory systems and methods of operating thereof, and computer readable storage media. An example memory system includes a memory and a controller. The memory includes blocks each includes memory cells, each of the memory cells is configured to store one of memory states, the memory states correspond to a group of read voltages, and a read voltage of the group of read voltages is configured to distinguish different memory states. The method includes performing a read operation on a selected memory cell in a selected block based on the read voltage of the group of read voltages when the memory system is re-powered on after power off, and determining an equivalent power off duration of the memory system.

### CROSS-REFERENCE TO RELATED APPLICATIONS

This application claims priority to and the benefit of Chinese Patent Application 2024107121570, filed on Jun. 3, 2024, which is hereby incorporated by reference in its entirety.

### TECHNICAL FIELD

Implementations of the present disclosure relate to the field of semiconductor technology, and in particular, to memory systems, operating methods thereof, and computer readable storage media.

### BACKGROUND

In recent years, a non-volatile memory is widely used in various electronic devices, such as personal computers, notebook computers, smart phones and tablet computers. Non-volatile memory (e.g., a three-dimensional NAND type memory) includes an array of memory cells included of a plurality of memory cells.

### BRIEF DESCRIPTION OF DRAWINGS

FIG. 1 is a block diagram of a system with a memory according to an implementation of the present disclosure;

FIG. 2A is a schematic diagram of a memory card with a memory according to an implementation of the present disclosure;

FIG. 2B is a schematic diagram of a solid state drive with a memory according to an implementation of the present disclosure;

FIG. 3 is a schematic diagram of a memory including a peripheral circuitry according to an implementation of the present disclosure;

FIG. 4 is a schematic cross-sectional view of a memory cell array including a memory string according to an implementation of the present disclosure;

FIG. 5 is a block diagram of a memory including a peripheral circuitry according to an implementation of the present disclosure;

FIG. 6 is a schematic diagram of a super block according to an implementation of the present disclosure;

FIG. 7 is a schematic diagram of performing a read operation on a triple-level unit according to an implementation of the present disclosure;

FIG. 8 is a flowchart of predicting an equivalent power off duration based on a close block according to some examples;

FIG. 9 is a preset mapping table between read offsets and equivalent retention durations at different erase range intervals according to some examples;

FIG. 10 is a schematic flowchart of a method for operating a memory system according to an implementation of the present disclosure;

FIG. 11 is a flowchart of predicting an equivalent power off duration according to an implementation of the present disclosure;

FIG. 12 is a threshold voltage distribution diagram after different equivalent retention durations according to an implementation of the present disclosure;

FIG. 13 is a preset mapping table between a preset number range and an equivalent retention duration at different erase range intervals according to an implementation of the present disclosure; and

FIG. 14 is a schematic diagram of updating an initial timestamp of a block according to an implementation of the present disclosure.

### DETAILED DESCRIPTION

The technical solutions in the implementations of the present disclosure will be clearly and completely described below with reference to the implementations of the present disclosure and the accompanying drawings, and it is obvious that the described implementations are only a part of the implementations of the present disclosure, not all implementations. All other implementations obtained by those of ordinary skill in the art without creative efforts shall fall within the scope of the present disclosure.

In the following description, numerous specific details are set forth in order to provide a more thorough understanding of the present disclosure. It will be apparent to those skilled in the art, however, that the present disclosure may be practiced without one or more of these details. In other examples, to avoid confusion with the present disclosure, some technical features well known in the art are not described; that is, not all features of the actual implementations will be described herein, and well-known functions and structures are not described in detail.

In the drawings, the dimensions of layers, regions, elements, and their relative sizes may be exaggerated for clarity. Like reference numbers refer to like elements throughout the present disclosure.

It should be appreciated that when an element or layer is referred to as being “on,” “adjacent to,” “connected to,” or “coupled to” the other element or layer, it may be directly on, adjacent to, connected to, or coupled to the other element or layer, or there may be an intervening element or layer. Conversely, when an element is referred to as being “directly on,” “directly adjacent,” “directly connected to,” or “directly coupled to” the other element or layer, there is no intervening element or layer. It should be appreciated that although the terms first, second, third, etc. may be used to describe various elements, components, regions, layers, and/or portions, these elements, components, regions, layers, and/or portions should not be limited by these terms. These terms are used merely to distinguish one element, component, region, layer, or portion from another element, component, region, layer, or portion. Thus, the first element, component, region, layer, or portion discussed below may be represented as a second element, component, region, layer, or portion without departing from the teachings of the present disclosure. When the second element, component, region, layer, or portion is discussed, it is not intended that the present disclosure necessarily include a first element, component, region, layer, or portion.

Spatial relationship terms, such as “beneath”, “under”, “lower”, “below”, “above”, “upper” and the like, may be used herein for ease of description to describe one element or feature's relationship to other elements or features as illustrated in the figures. It should be appreciated that in addition to the orientations shown in the figures, the spatial relation term is intended to encompass different orientations of the devices in use and operation. For example, if the devices in the figures are flipped, then an element or feature as described as “under” or “below” or “beneath” the other element or feature will be oriented “above” the other element or feature. Thus, the example terms “under” and “beneath” may include both upper and lower orientations. The device may be additionally oriented (rotated 90 degrees or at other orientations) and the spatial descriptors used herein may be interpreted accordingly.

The terminology used herein is for the purpose of describing example implementations only and is not intended as a limitation of the present disclosure. As used herein, the singular forms “a,” “an,” and “the” are intended to include plural forms as well, unless the context clearly indicates otherwise. It should also be understood that the terms “comprise” and/or “include”, when used in this specification, determine the presence of stated features, integers, steps, operations, elements, and/or components, but do not preclude the presence or addition of one or more other features, integers, steps, operations, elements, components, and/or groups. As used herein, the term “and/or” comprises any and all combinations of related listed items.

For a thorough understanding of the present disclosure, detailed operations and detailed structures will be presented in the following description in order to explain the technical solutions of the present disclosure. Example implementations of the present disclosure are described in detail below; however, the present disclosure may also have other implementations in addition to these detailed described ones.

For ease of understanding, the memory in the implementations of the present disclosure is illustrated by using a three-dimensional NAND type flash memory as an example.

Currently, there is an urgent need to improve memory systems and the operation methods thereof.

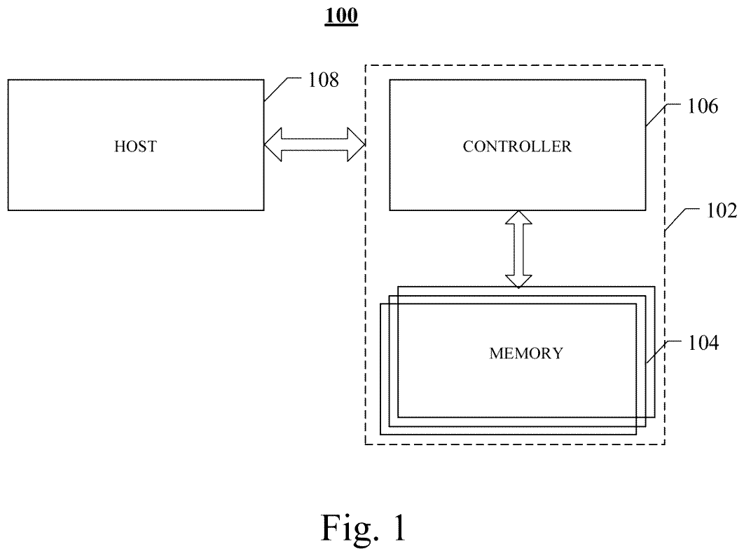

Referring to FIG. 1, FIG. 1 is a block diagram of a system with a memory according to an implementation of the present disclosure. As shown in FIG. 1, the system 100 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a storage therein.

As shown in FIG. 1, the system 100 may include a host 108 and a memory system 102 (as illustrated by a dashed block in FIG. 1) having one or more memories 104 and a controller 106. The host 108 may be a processor (for example, a central processing unit (CPU)) of an electronic device or a system on chip (SoC) (for example, an application processor (AP)). The host 108 may be configured to send or receive data to or from the memory 104.

In some implementations, the controller 106 is coupled to the memory 104 and the host 108 and is configured to control the memory 104. The controller 106 may manage data stored in the memory 104 and communicate with the host 108.

In some implementations, the controller 106 is designed to operate in a low duty cycle environment, such as a Secure Digital (SD) card, a Compact Flash (CF) card, a Universal Serial Bus (USB) flash drive, or other medium for use in electronic devices such as personal computers, digital cameras, and mobile phones.

In some implementations, the controller 106 is designed to operate in a high duty cycle environment, such as a solid state drive (SSD) or embedded Multi-Media Card (eMMC) that is used as a data storage for mobile devices such as smart phones, tablet computers, laptop computers, and the like, and enterprise storage array.

The controller 106 may be configured to control operations of the memory 104, such as read, erase, and program operations. The controller 106 may also be configured to manage various functions with respect to data stored in or to be stored in the memory 104, including, but not limited to, bad block management, garbage collection, logical address to physical address translation, wear leveling, and the like. In some implementations, the controller 106 is further configured to process Error Correcting Code (ECC) with respect to data read from or written to the memory 104.

The controller 106 may also perform any other suitable functions, such as formatting the memory 104. The controller 106 may communicate with an external device (e.g., host 108) according to a particular communication protocol. For example, the controller 106 may communicate with an external device through at least one of various interface protocols, such as a USB protocol, an MMC protocol, a Peripheral Component Interconnect (PCI) protocol, a PCI express (PCI-E) protocol, an Advanced Technology Attachment (ATA) protocol, a serial ATA protocol, a parallel ATA protocol, a Small Computer System Interface (SCSI) protocol, an Enhanced Small Disk Interface (ESDI) protocol, an Integrated Drive Electronics (IDE) protocol, a Firewire protocol, and so forth.

The controller 106 and the one or more memories 104 may be integrated into various types of storage devices, for example, included in the same package (e.g., Universal Flash Storage (UFS) package or eMMC package). That is, the memory system 102 can be implemented and packaged into different types of end electronic products.

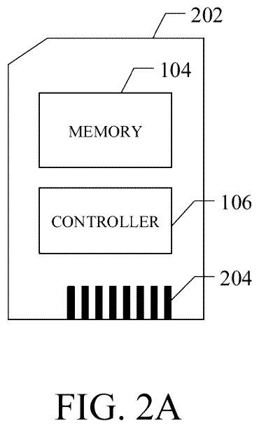

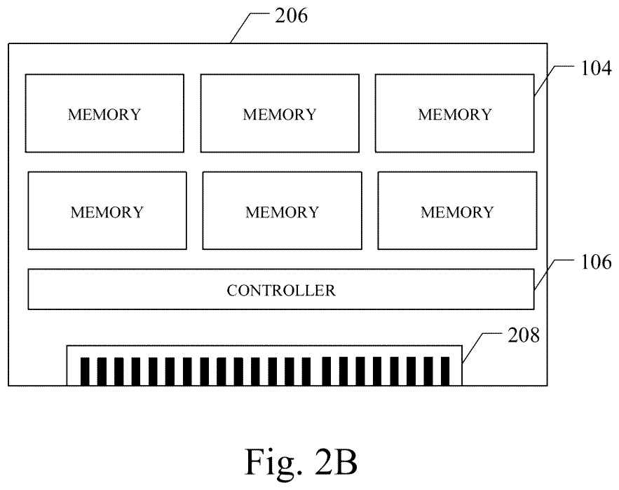

Referring to FIG. 2A, FIG. 2A is a schematic diagram of a memory card with a memory according to an implementation of the present disclosure. As shown in FIG. 2A, the controller 106 and the single memory 104 can be integrated into a memory card 202. The memory card 202 can include a Personal Computer Memory Card International Association (PCMCIA) card, a CF card, a Smart Media (SM) card, a memory stick, a multimedia card (e.g., MMC, Reduced Size MMC (RS-MMC), Micro MMC (micro MMC)), SD (e.g., SD, mini SD (miniSD), micro SD (microSD), Secure Digital High Capacity (SDHC) card), UFS, and the like. The memory card 202 may also include a memory card connector 204 that couples the memory card 202 with a host (e.g., host 108 in FIG. 1).

Referring to FIG. 2B, FIG. 2B is a schematic diagram of a solid state drive with a memory according to an implementation of the present disclosure. As shown in FIG. 2B, the controller 106 and the plurality of memories 104 may be integrated into the solid state drive 206. The solid state drive 206 may also include a solid state drive connector 208 that couples the solid state drive 206 with a host (e.g., host 108 in FIG. 1). In some implementations, the storage capacity and/or operating speed of the solid state drive 206 is greater than the storage capacity and/or operating speed of the memory card 202.

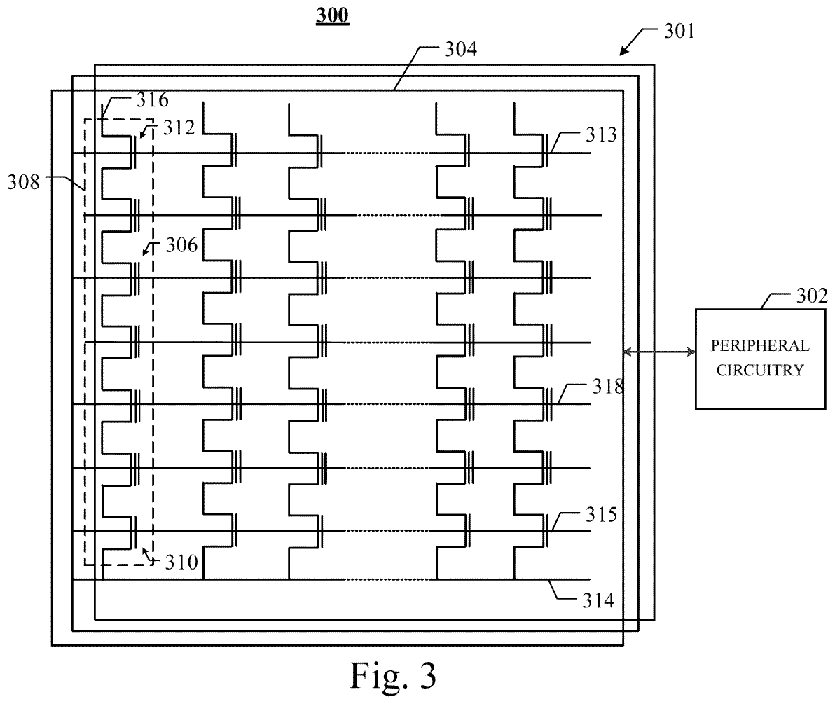

Referring to FIG. 3, FIG. 3 is a schematic diagram of a memory including a peripheral circuitry according to an implementation of the present disclosure. Memory 300 may be an example of memory 104 in FIG. 1. The memory 300 may include a memory cell array 301 and a peripheral circuitry 302 coupled to the memory cell array 301. The memory cell array 301 may be an array of NAND type flash memory cells, where the memory cells 306 are provided in the form of an array of memory strings 308, each extending vertically above a substrate (not shown in FIG. 3). In some implementations, each memory string 308 includes a plurality of memory cells 306 coupled in series and stacked vertically. Each memory cell 306 may hold a continuous analog value, e.g., voltage or charge, which depends on the number of electrons trapped within a region of memory cell 306. Each memory cell 306 can be either a floating gate type of memory cell including a floating-gate transistor or a charge trap type of memory cell including a charge-trap transistor.

In some implementations, each memory cell 306 may be a single-level Cell (SLC) having two possible memory states and thus may store one bit of data. For example, the SLC may have a first memory state “1” and a second memory state “0”, where the threshold voltage distribution of the first memory state “1” may correspond to the first voltage range, and the threshold voltage distribution of the second memory state “0” may correspond to the second voltage range. The first memory state is an erased state, and the second memory state is a programmed state. In some implementations, each memory cell 306 is a multi-level cell (MLC) capable of storing more than a single bit of data in more than four memory states. For example, the MLC may store two bits of data per cell, three bits of data per cell (also known as triple-level cell (TLC)), or four bits of data per cell (also known as quad-level cell (QLC)). Each MLC may be programmed to assume a voltage range of a possible threshold voltage distribution. In one example, if each MLC stores two bits of data, the MLC may have a first memory state “11”, a second memory state “10”, a third memory state “01”, and a fourth memory state “00”, where threshold voltage distributions of the first, second, third, and fourth memory states correspond to the first, second, third, and fourth voltage ranges, respectively. The first memory state is an erased state, and the second, third and fourth memory states are each programmed states. Similarly, the TLC may have 8 memory states, including an erased state and 7 programmed states; the QLC may have 16 memory states, including an erased state and 15 programmed states.

As shown in FIG. 3, each memory string 308 may include a source selective transistor (SST) 310 at its source end and a drain selective transistor (DST) 312 at its drain end. The source selective transistor 310 and the drain selective transistor 312 may be configured to activate the selected memory string 308 (a column of the array) during a read operation and a program operation. In some implementations, the sources of the memory strings 308 in the same block 304 (Block) are coupled through the same source line (e.g., common SL) 314. In other words, in some implementations, all the memory strings 308 in the same block have an array common source (ACS). In some implementations, the drain of the drain selective transistor 312 of each memory string 308 is coupled to a respective bit line (BL) 316 from which data can be read or written via an output bus (not shown in FIG. 3). In some implementations, each memory string 308 is configured to be selected or deselected by applying a select voltage (e.g., higher than a threshold voltage of the drain selective transistor 312) or a deselect voltage (e.g., 0V) to the respective drain selective transistor 312 via one or more drain selective lines (DSL) 313 and/or by applying a select voltage (e.g., higher than a threshold voltage of the source selective transistor 310) or a deselect voltage (e.g., 0V) to the respective source selective transistor 310 via one or more source selective lines (SSL) 315.

As shown in FIG. 3, the memory strings 308 may be organized into a plurality of blocks 304, each of which may have a source line 314 (e.g., a common SL coupled to ground). In some implementations, each block 304 is a basic data unit for performing an erase operation; that is, all memory cells 306 on the same block 304 are erased simultaneously. To erase the memory cells 306 in the selected block, the source lines 314 coupled to a selected block as well as an unselected block in the same plane as the selected block can be biased with an erase voltage (Vers), such as a high positive voltage (e.g., 20 V or higher). It should be understood that in some examples, the erase operation may be performed at a half block level, at a quarter block level, or at a level having any suitable number of blocks or any suitable fraction of a block. Memory cells 306 of adjacent memory strings 308 may be coupled by a word line (WL) 318 that select which row of memory cells 306 is affected by read operations and program operations. In some implementations, in the same block 304, the memory cells 306 coupled to the same word line 318 may constitute at least one memory page. Each word line 318 may include a plurality of control gates (gate electrodes) at each memory cell 306 in a respective memory page and a gate line coupled to the control gate.

It should be noted that the above-mentioned memory page may be considered as a physical page, which refers to a layer of memory cells on the physical level. For a SLC, each memory cell may store 1 bit of information, so that information stored in a layer of memory cells (that is, 1 physical page) on the physical level corresponds to information of 1 logical page. For an MLC, each memory cell may store 2 bits of information, so that information stored in a layer of memory cells (that is, 1 physical page) on a physical level corresponds to information of 2 logical pages. For a TLC, each memory cell may store 3 bits of information, so that information stored in a layer of memory cells (that is, 1 physical page) on the physical level corresponds to information of 3 logical pages. For a QLC, each memory cell may store 4 bits of information, so that information stored in a layer of memory cells (that is, 1 physical page) on the physical level corresponds to information of 4 logical pages.

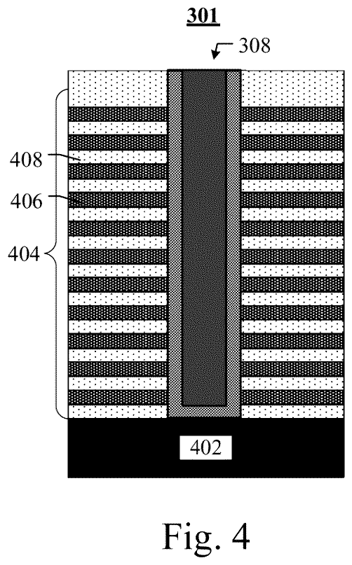

Referring to FIG. 4, FIG. 4 is a schematic cross-sectional view of a memory cell array including a memory string according to an implementation of the present disclosure. As shown in FIG. 4, a memory string 308 may extend vertically through a memory stack 404 above a substrate 402. Substrate 402 may include silicon (e.g., single crystalline silicon), silicon germanium (SiGe), gallium arsenide (GaAs), germanium (Ge), silicon on insulator (SOI), germanium on insulator (GOI), or any other suitable materials.

The memory stack 404 may include alternating gate conductive layers 406 and gate dielectric layers 408. The number of pairs of gate conductive layers 406 and gate dielectric layers 408 in the memory stack 404 may determine the number of memory cells 306 in the memory cell array 301. The gate conductive layer 406 may include a conductive material including, but not limited to, tungsten (W), cobalt (Co), copper (Cu), aluminum (Al), polysilicon, doped silicon, silicide, or any combination thereof. In some implementations, each of the gate conductive layers 406 includes a metal layer, such as a tungsten layer. In some implementations, each gate conductive layer 406 includes a doped polysilicon layer. Each of the gate conductive layers 406 may include a control gate surrounding the memory cell 306, and the gate conductive layer 406 at the top of the memory stack 404 may extend laterally as the drain selective line 313, the gate conductive layer 406 at the bottom of the memory stack 404 may extend laterally as the source selective line 315, or the gate conductive layers 406 between the drain selective line 313 and the source selective line315 may extend laterally as the word lines 318.

As shown in FIG. 4, the memory string 308 includes a channel structure that extends vertically through the memory stack 404. In some implementations, the channel structure includes a channel hole filled with semiconductor material(s) (e.g., as a semiconductor channel) and dielectric material(s) (e.g., as a memory film). In some implementations, the semiconductor channel includes silicon, e.g., polysilicon. In some implementations, the memory film is a composite dielectric layer including a tunneling layer, a memory layer (also referred to as a “charge trapping/storage layer”), and a blocking layer. The channel structure may have a cylindrical shape (e.g., a pillar shape). According to some implementations, the semiconductor channel, the tunneling layer, the memory layer, and the blocking layer are arranged radially from the center of the pillar toward the outer surface of the pillar in this order. The tunneling layer may include silicon oxide, silicon oxynitride, or any combination thereof. The memory layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

According to some implementations, a well (e.g., a P-well and/or an N-well) may be formed in the substrate 402, and a source end of the memory string 308 is in contact with the well. For example, a source line may be coupled to the well to apply an erase voltage to the well (e.g., the source of the memory string) during an erase operation. In some implementations, the memory string 308 also includes a channel plug at the drain end of the memory string 308. It should be understood that although not illustrated in FIG. 4, additional components of the memory cell array 301 may be formed including, but not limited to, a gate line slit/a source contact, a local contact and an interconnect layers and the like.

Referring back to FIG. 3, the peripheral circuitry 302 may be coupled to the memory cell array 301 through a bit lines 316, a word line 318, a source line 314, a source selective line 315, and a drain selective line 313. The peripheral circuitry 302 may include any suitable analog, digital, and mixed-signal circuitry for facilitating operation of the memory cell array 301 by applying and sensing voltage signals and/or current signals to and from each target memory cell via the bit line 316, word line 318, source line 314, source selective line 315, and drain selective line 313. The peripheral circuitry 302 may include various types of peripheral circuits formed using metal-oxide-semiconductor (MOS) technology.

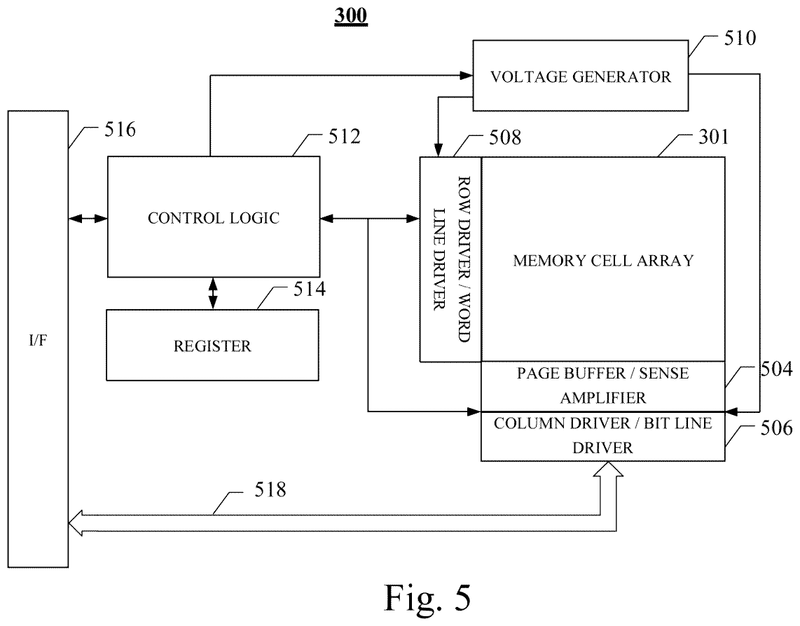

Referring to FIG. 5, FIG. 5 is a block diagram of a memory including a peripheral circuitry according to an implementation of the present disclosure. As shown in FIG. 5, the peripheral circuitry includes a page buffer/sense amplifier 504, a column driver/bit line driver 506, a row driver/word line driver 508, a voltage generator 510, a control logic 512, a register 514, an interface 516 (I/F), and a data bus 518. It should be understood that in some examples, additional peripheral circuits not shown in FIG. 5 may also be included.

The page buffer/sense amplifier 504 may be configured to read and program (write) data from and to the memory cell array 301 according to a control signal from the control logic 512. In another example, the page buffer/sense amplifier 504 may perform a program verify operation to ensure that the data has been properly programmed into the memory cell 306 coupled to the selected word line 318. In yet another example, the page buffer/sense amplifier 504 may also sense a low power signal from the bit line 316 representing a data bit stored in the memory cell 306, and amplify the small voltage swing to an identifiable logic level in a read operation. Column driver/bit line driver 506 may be configured to be controlled by control logic 512 and select one or more memory strings 308 by applying a bit line voltage generated from voltage generator 510.

The row driver/word line driver 508 may be configured to be controlled by the control logic 512 and select/deselect a block of the memory cell array 301 and select/deselect a word line 318 of the block. The row driver/word line driver 508 may also be configured to drive the word line 318 using the word line voltage generated from the voltage generator 510. In some implementations, row driver/word line driver 508 may also select/deselect and drive source selective line315 and drain selective line 313. As described in detail below, the row driver/word line driver 508 is configured to perform an erase operation on the memory cells 306 coupled to the selected word line(s) 318. The voltage generator 510 may be configured to be controlled by the control logic 512 and generate a word line voltage (e.g., a read voltage, a program voltage, a pass voltage, a local voltage, a verify voltage, etc.), a bit line voltage, and a source line voltage to be supplied to the memory cell array 301.

Control logic 512 may be coupled to each peripheral circuit described above and configured to control operation of each peripheral circuit. Register 514 may be coupled to control logic 512 and include a status register, a command register, and an address registers for storing status information, command operation code (OP code), and command address for controlling operation of each peripheral circuit. The interface 516 may be coupled to the control logic 512 and act as a control buffer to buffer a control command received from the host (not shown in FIG. 5) and relay it to the control logic 512 and buffer status information received from the control logic 512 and relay it to the host. The interface 516 may also be coupled to the column driver/bit line driver 506 via a data bus 518 and act as a data input/output (I/O) interface and a data buffer to buffer data, and relay or buffer data to or from the memory cell array 301.

After performing a program operation on a memory cell of a memory, an idle time is passed, and a read operation is performed on the memory cell. In this case, a threshold voltage distribution of a programmed memory cell is shifted, and it is difficult to meet a quality of service (QoS) requirement for a subsequent one-shot read pass of a memory, such as an enhanced solid state drive (Enhanced SSD). Therefore, before performing the read operation on the memory, it is necessary to re-determine the read voltage when the subsequent read operation is performed according to the state information of the memory cell (e.g., the threshold voltage distribution state information of the memory cell). However, the state information of the memory cell is related to the equivalent retention duration. In general, the greater the equivalent retention duration (Data Retention) of the stored data on the block is, the greater the threshold voltage shift of the memory cell is. Therefore, it is possible to determine the equivalent retention duration of the stored data on the block according to the threshold voltage distribution state information of the memory cell.

After the memory system is powered off, the equivalent power off duration of the memory system cannot be recorded, and after the memory system is re-powered on, the equivalent power off duration of the memory system needs to be determined according to the threshold voltage distribution state information of the memory cell; therefore, the equivalent retention duration of the data stored in the block is updated according to the equivalent power off duration of the memory system; and then the read voltage when the read operation is subsequently performed is re-determined according to the updated equivalent retention duration of the data stored in the block.

Before introducing the implementations of the present disclosure, technical terms such as the initial equivalent retention duration, the equivalent power off duration, and the equivalent retention duration involved in the implementations of the present disclosure need to be explained first.

Here, the equivalent retention duration is determined based on the temperature and the physical retention duration, and in the case that the temperature conditions are the same, the physical retention durations can be directly compared; whereas in the case that the temperature conditions are different, the physical retention durations cannot be directly compared, and it is necessary to perform a conversion based upon the temperature and the physical retention duration to obtain the equivalent retention duration at the same temperature, and then the equivalent retention durations are compared.

Here, the initial equivalent retention duration (which may also be referred to as “initial timestamp”) refers to an equivalent retention duration of the data stored in the block before the memory system is powered off, where the initial equivalent retention duration is determined based on the temperature and the initial physical retention duration.

Here, the equivalent power off duration refers to a duration after the memory system is powered off and before the memory system is re-powered on, that is, an equivalent power off duration of the memory system in a power off process, where the equivalent power off duration is determined based on the temperature and the physical power-off duration.

Here, the equivalent retention duration (which may also be referred to as “update timestamp”) refers to the sum of the initial equivalent retention duration and the equivalent power off duration, which includes both the initial equivalent retention duration of the data stored in the block before the memory system is powered off, and the equivalent power off duration after the memory system is powered off and before the memory system is re-powered on, where the equivalent retention duration is determined based on the temperature and the physical retention duration.

In some implementations, a typical temperature may be selected, and the temperature and the physical retention duration are converted to obtain the equivalent retention duration. For example, 55° C. can be selected as a typical temperature, and the physical retention duration under other temperature conditions can be converted into an equivalent retention duration at 55° C. The specific value of the typical temperature is not specifically limited in the implementations of the present disclosure, and those skilled in the art may flexibly select the typical temperature according to actual conditions.

Before introducing the implementations of the present disclosure, the relevant classification of the blocks involved in the implementations of the present disclosure needs to be explained first. The blocks may be divided into an open block, a close block, an erase block and an orphan block. The definitions of the open block, the close block, the erase block and the orphan block are explained below.

Here, the open block (which may also be referred to as a “partially programmed block”) refers to a block that has started a program operation, and is in an open state, and in which at least one memory page is not yet programmed. Illustratively, some of the memory cells in the open block have been programmed and the remaining memory cells have not yet been programmed.

Here, the close block (which may also be referred to as a “full block”) refers to a block in which all memory cells have been programmed.

Here, the erase block refers to a block that has been performed an erase operation and in which all memory cells are in an erased state.

Before introducing the definition of the orphan block, the definition of the super block (SPB) needs to be explained first.

Here, the memory system includes a memory and a controller coupled to the memory, and the memory may include a plurality of dies, for example, dies Die_0, Die_1, Die_2 to Die_N, where N is an integer greater than or equal to 1. The number of dies included in the memory are not specifically limited in the implementations of the present disclosure.

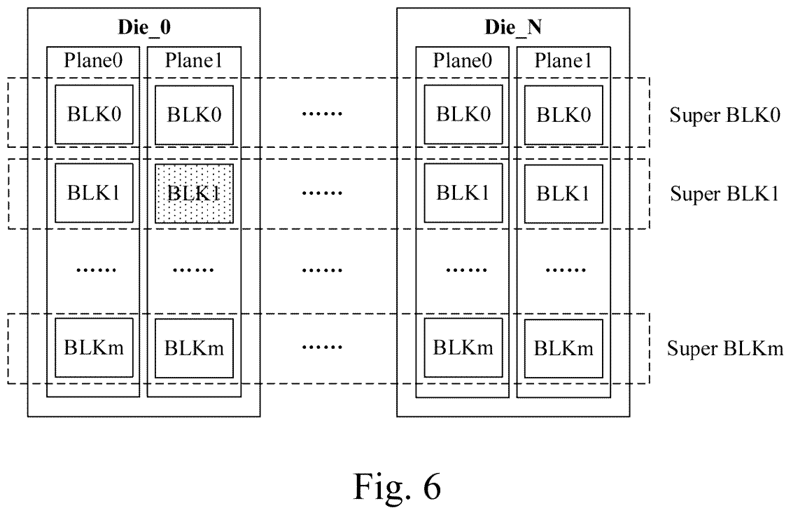

Here, in dies Die_0, Die_1, Die_2 to Die_N, each die may include one or more memory planes. Referring to FIG. 6, FIG. 6 is a schematic diagram of a super block according to an implementation of the present disclosure. As shown in FIG. 6, each die includes two memory planes, Plane0 and Plane1. Each memory plane may include a plurality of blocks, such as BLK0, BLK1, BLK2 to BLKm; where m is an integer greater than or equal to 1. The number of memory planes included in each die and the number of blocks included in each memory plane are not specifically limited in the implementations of the present disclosure.

Illustratively, the controller may manage the die in units of superblocks. A super block may include at least one block within at least one die. For example, one super block may include blocks having serial numbers which are the same in all memory planes in all dies. For example, the blocks BLK0 included in each memory plane of each of the dies Die_0 to Die_N may collectively constitute the super block Super BLK0; and the blocks BLK1 included in each memory plane of each die in Die_0 to Die_N may collectively constitute the super block Super BLK1. In this way, dies Die_0, Die_1, Die_2 to Die_N may include super blocks Super BLK0, and Super BLK1 to Super BLKm; where m is an integer greater than or equal to 1, and each super block may include 2N blocks.

Here, a bad super block refers to a super block that cannot be normally used, and all blocks included in the bad super block are bad blocks; or the number of bad blocks in all blocks included in the bad super block exceeds a certain number. That is, the bad super block may also include a good block which operates normally. For example, one super block may include 8 blocks, where 6 blocks are bad blocks, and the remaining 2 blocks are good blocks. In this case, the good block in the bad super block may be referred to as an orphan block.

Before introducing the implementations of the present disclosure, the program operation and the read operation of the multi-level cell needs to be explained first.

It should be noted that, when the memory system receives the command CMD and the host data DATA corresponding to the program operation from the host, the controller in the memory system may perform a randomization processing on the host data DATA, and store the randomized processed data in the memory. For example, when the memory performs a program operation on the TLC, the controller may perform a randomization processing on the host data DATA received from the host, and the first, second, third, fourth, fifth, sixth, seventh and eighth data after the randomization processing are 111, 011, 001, 000, 010, 110, 100, and 101, respectively, and the first to eighth data have the same number of bits. Correspondingly, when performing the read operation, the raw data read from the memory also needs to be derandomized to obtain the host data DATA.

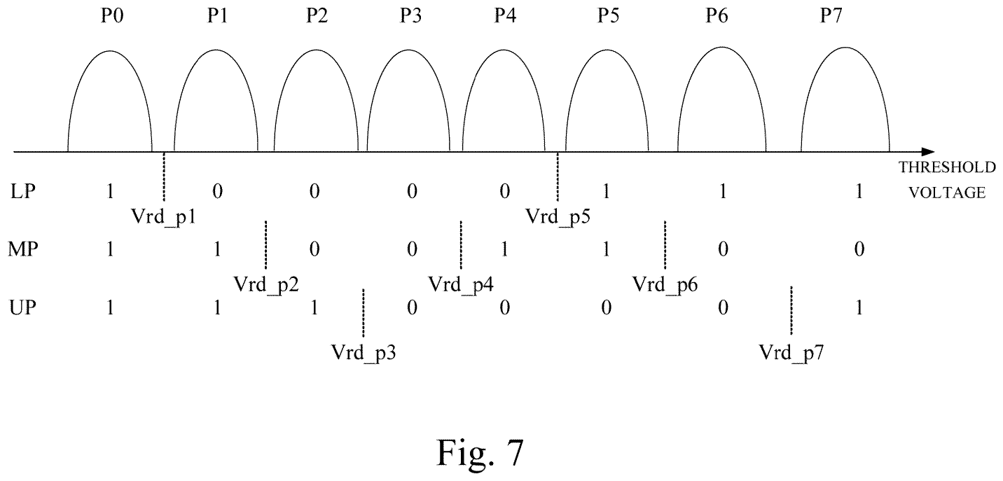

Here, taking a TLC as an example of the memory cell to illustrate the read operation of the memory cell. The same word line may be coupled to three logical pages of the same row, and the three logical pages may include a low page (LP), a middle page (MP), and an up page (UP). Referring to FIG. 7, FIG. 7 is a schematic diagram of performing a read operation on a triple-level unit according to an implementation of the present disclosure. As shown in FIG. 7, after performing the program operation, each memory cell of the TLC may store three bits of data, and may have a first memory state “111”, a second memory state “011”, a third memory state “001”, a fourth memory state “000”, a fifth memory state “010”, a sixth memory state “110”, a seventh memory state “100”, and an eighth memory state “101”. The threshold voltage distributions of the first, second, third, fourth, fifth, sixth, seventh, and eighth memory states correspond to the first, second, third, fourth, fifth, sixth, seventh, and eighth voltage ranges, respectively. Here, the first memory state is an erased state (e.g., P0), and the second, third, fourth, fifth, sixth, seventh, and eighth memory states are sequentially first, second, third, fourth, fifth, sixth and seventh programmed states (e.g., P1 to P7).

Here, in the read operation of the LP, the read operation may be performed by using the first read voltage Vrd_p1 and the fifth read voltage Vrd_p5; in the read operation of the MP, the read operation may be performed by using the second read voltage Vrd_p2, the fourth read voltage Vrd_p4, and the sixth read voltage Vrd_p6; and in the read operation of the UP, the read operation may be performed by using the third read voltage Vrd_p3 and the seventh read voltage Vrd_p7.

Here, in the read operation of the LP, the read operations using the first read voltage Vrd_p1 and the fifth read voltage Vrd_p5 may be performed sequentially.

When the read operation using the first read voltage Vrd_p1 is performed, the memory cell having a threshold voltage less than the first read voltage Vrd_p1 is the ON cell, and the memory cell having a threshold voltage greater than the first read voltage Vrd_p1 is the OFF cell. Thus, data “1” may be read from a memory cell having a threshold voltage less than the first read voltage Vrd_p1, and data “0” may be read from a memory cell having a threshold voltage greater than the first read voltage Vrd_p1. Since the first read voltage Vrd_p1 is the minimum read voltage in the read voltages configured to identify the LP data, the data “1” read from the memory cell having a threshold voltage less than the first read voltage Vrd_p1 is the determined data. For example, the data “1” read from a memory cell corresponding to the erase state P0 and having a threshold voltage less than the first read voltage Vrd_p1 is the determined data.

Since the read operation of the LP is completed by further performing the read operation using the fifth read voltage Vrd_p5, the data “0” read from the memory cell having a threshold voltage greater than the first read voltage Vrd_p1 is not the determined data.

When the read operation using the fifth read voltage Vrd_p5 is performed, a ground voltage may be applied to the bit line corresponding to the memory cell with the determined data in the erased state P0, and the precharge voltage may be applied to the remaining bit lines.

When the read operation using the fifth read voltage Vrd_p5 is performed, data “1” may be read from the memory cells having the first programmed state P1 to the fourth programmed state P4, and data “0” may be read from the memory cells having the fifth programmed state P5 to the seventh programmed state P7. According to the algorithm of the LP read operation, the data read using the fifth read voltage Vrd_p5 may be flipped and stored in the page buffer, thus the data read from the memory cells corresponding to the first programmed state P1 to the fourth programmed state P4 and having a threshold voltage less than the fifth read voltage Vrd_p5 may be determined to be “0”, and the data read from the memory cells corresponding to the fifth programmed state P5 to the seventh programmed state P7 and having a threshold voltage greater than the fifth read voltage Vrd_p5 may be determined to be “1”.

When the read operation of the LP ends, a read operation of the MP may be performed. Here, in the read operation of the MP, the read operations using the second read voltage Vrd_p2, the fourth read voltage Vrd_p4 and the sixth read voltage Vrd_p6 may be performed sequentially.

When a read operation using the second read voltage Vrd_p2 is performed, data “1” may be read from a memory cell having a threshold voltage less than the second read voltage Vrd_p2, and data “0” may be read from a memory cell having a threshold voltage greater than the second read voltage Vrd_p2. Since the second read voltage Vrd_p2 is the minimum read voltage in the read voltages configured to identify the MP data, the data “1” read from the memory cell having a threshold voltage less than the second read voltage Vrd_p2 is the determined data. For example, the data “1” read from a memory cell corresponding to the erased state P0 and the first programmed state P1 and having a threshold voltage less than the second read voltage Vrd_p2 is the determined data.

Since the read operation of the MP is completed by further performing the read operations using the fourth read voltage Vrd_p4 and the sixth read voltage Vrd_p6, data “0” read from a memory cell having a threshold voltage greater than the second read voltage Vrd_p2 is not the determined data.

When a read operation using the fourth read voltage Vrd_p4 is performed, a ground voltage may be applied to the bit lines corresponding to the memory cells having the determined data in the erased state P0 and the first programmed state P1, and the precharge voltage may be applied to the remaining bit lines.

When a read operation using the fourth read voltage Vrd_p4 is performed, data “1” may be read from the memory cells having the second programmed state P2 and the third programmed state P3, and data “0” may be read from the memory cells having the fourth programmed state P4 to the seventh programmed state P7. According to the algorithm of the MP read operation, the data read using the fourth read voltage Vrd_p4 may be flipped and stored in the page buffer, thus the data read from the memory cells corresponding to the second programmed state P2 and the third programmed state P3 and having a threshold voltage less than the fourth read voltage Vrd_p4 may be determined to be “0”.

Since the read operation of the MP is completed by further performing the read operation using the sixth read voltage Vrd_p6, the data “1” read from a memory cell having a threshold voltage greater than the fourth read voltage Vrd_p4 is not the determined data.

When a read operation using the sixth read voltage Vrd_p6 is performed, a ground voltage may be applied to the bit lines corresponding to the memory cells having the determined data in the erased state P0 and the first to third programmed states P1 to P3, and the precharge voltage may be applied to the remaining bit lines.

When the read operation using the sixth read voltage Vrd_p6 is performed, the data read from the memory cells corresponding to the fourth programmed state P4 and the fifth programmed state P5 and having a threshold voltage less than the sixth read voltage Vrd_p6 may be determined to be “1”, and the data read from the memory cells corresponding to the sixth programmed state P6 and the seventh programmed state P7 and having a threshold voltage greater than the sixth read voltage Vrd_p6 may be determined to be “0”.

When the read operation of the MP ends, a read operation of the UP may be performed. Here, in the read operation of the UP, the read operations using the third read voltage Vrd_p3 and the seventh read voltage Vrd_p7 may be sequentially performed.

When a read operation using the third read voltage Vrd_p3 is performed, data “1” may be read from a memory cell having a threshold voltage less than the third read voltage Vrd_p3, and data “0” may be read from a memory cell having a threshold voltage greater than the third read voltage Vrd_p3. Since the third read voltage Vrd_p3 is the minimum read voltage in the read voltages configured to identify the UP data, the data “1” read from the memory cell having a threshold voltage less than the third read voltage Vrd_p3 is the determined data. For example, the data “1” read from memory cells corresponding to the erased state P0, the first programmed state P1, and the second programmed state P2 and having a threshold voltage less than the third read voltage Vrd_p3 is the determined data.

Since the read operation of the UP is completed by further performing the read operation using the seventh read voltage Vrd_p7, the data “0” read from a memory cell having a threshold voltage greater than the third read voltage Vrd_p3 is not the determined data.

When a read operation using the seventh read voltage Vrd_p7 is performed, a ground voltage may be applied to the bit lines corresponding to the memory cells having the determined data in the erased state P0, the first programmed state P1, and the second programmed state P2, and the precharge voltage may be applied to the remaining bit lines.

When a read operation using the seventh read voltage Vrd_p7 is performed, data “1” may be read from the memory cells having the third programmed state P3 to the sixth programmed state P6, and data “0” may be read from the memory cell having the seventh programmed state P7. According to the algorithm of the UP read operation, the data read using the seventh read voltage Vrd_p7 may be flipped and stored in the page buffer, thus the data read from the memory cells corresponding to the third programmed state P3 to the sixth programmed state P6 and having a threshold voltage less than the seventh read voltage Vrd_p7 may be determined to be “0”, and the data read from the memory cell corresponding to the seventh programmed state P7 and having a threshold voltage greater than the seventh read voltage Vrd_p7 may be determined to be “1”.

It should be noted that because the TLC includes 8 memory states, performing a read operation on the TLC to distinguish the above 8 memory states needs to use a group of read voltages, and the group of read voltages includes 7 read voltages. Only after all the read voltages in the group of read voltages are used, a read result may be obtained, where the read result refers to specific data stored in a memory cell as obtained by reading. For example, the three-bit data stored in a memory cell may be read as “101”.

However, a Single-Level Read (SLR) operation refers to performing a read operation by using a read voltage in a group of read voltages to obtain a number of memory cells having a threshold voltage greater than or equal to the read voltage and a number of memory cells having a threshold voltage less than the read voltage as a read result. Data in a memory cell having a threshold voltage less than the read voltage may be determined to be “1”, and data in a memory cell having a threshold voltage greater than or equal to the read voltage may be determined to be “0”. Of course, the “1” and “0” here do not represent the actual stored data in the memory cell, and memory cells are classified according to the magnitude relationship between the read voltage and the threshold voltage of the memory cell, where the memory cell having a threshold voltage less than the read voltage is classified as the first type, and the data stored in the first type of memory cells is considered as “1”; and the memory cell having a threshold voltage greater than or equal to the read voltage is classified as the second type, and the data stored in the second type of memory cells is considered as “0”.

The difference between the above two read operations lies in the following two aspects. In the first aspect, the number of read voltages used to perform the read operation is different, where all read voltages in the group of read voltages need to be used in the TLC read operation, and only one read voltage in the group of read voltages needs to be used in the SLR operation. In the second aspect, the read results are different, where the specific data stored in the memory cell can be obtained as the read result by reading in the TLC read operation, and the specific data stored in the memory cell cannot be obtained by reading in the SLR operation, in which the count value of “1” and the count value of “0” are used as the read results, and “0” and “1” are only used to distinguish the magnitude relationship between the threshold voltage and the read voltage of the memory cell.

The process of determining the equivalent power off duration using the read offset corresponding to the minimum fail bit count (FBC) is described in detail below.

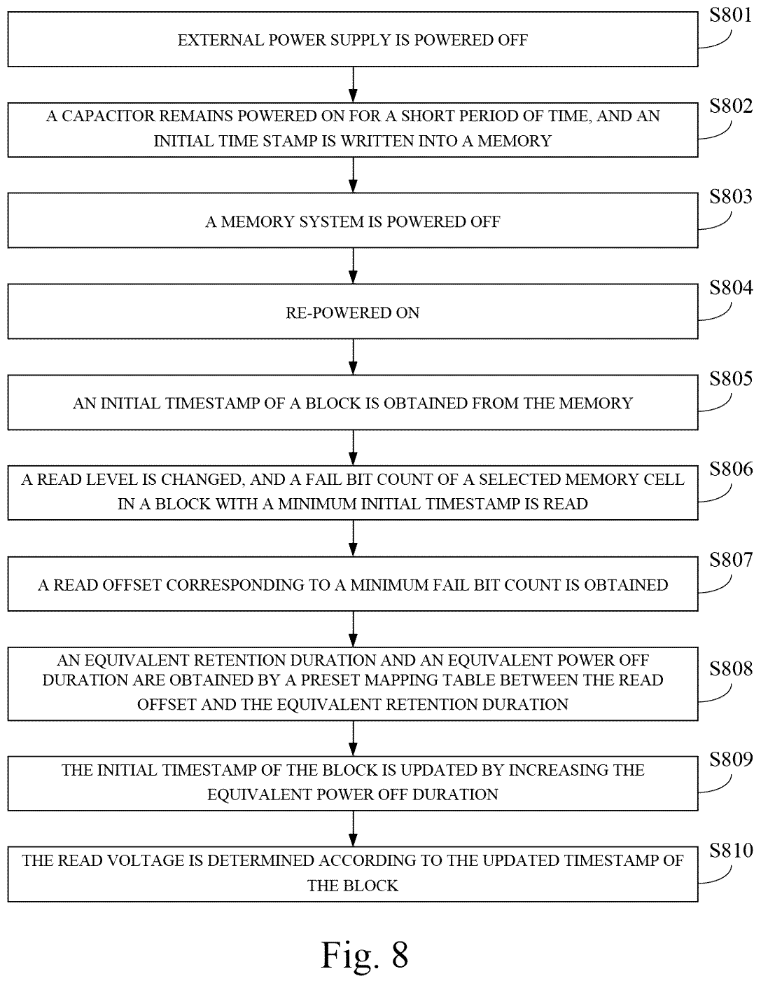

FIG. 8 is a flowchart of predicting an equivalent power off duration based on a close block according to some examples of the present disclosure. As shown in FIG. 8, in operation S801, an external power is off, that is, an external power supply is turned off.

In operation S802, a capacitor remains powered on for a short period of time, and the initial time stamp is written into the memory.

Here, after the external power supply is powered off and before the memory system is powered off, the capacitor may also remain powered on for a short period of time during which the initial timestamp of the block may be written to the memory. The initial timestamp refers to the equivalent retention duration of the data stored in the block before the memory system is powered off. Of course, the initial timestamp may also be referred to as an initial equivalent retention duration, and the initial equivalent retention duration is determined based on the temperature and the initial physical retention duration.

Here, the initial timestamp refers to the equivalent retention duration of the data stored in the block before the memory system is powered off, therefore only the blocks to which the data is written have initial timestamps, such as open blocks and close blocks. That is, the blocks to which the data is not written do not have initial timestamps. For example, timing may start from writing the first page of data to the block, and the initial timestamp is recorded; of course, timing may also start from the block be written and full of data, and the initial timestamp is recorded.

In operation S803, the memory system is powered off, that is, the memory system is turned off.

In operation S804, re-powered on is performed, that is, the external power supply is re-powered on and the memory system is re-powered on.

Here, from operation S803 to operation S804, that is, from the memory system being powered off to the memory system being re-powered on, the memory system will experience an equivalent power off duration, so that the memory system cannot record the equivalent power off duration.

In operation S805, an initial timestamp of the block is obtained from the memory.

Here, the initial timestamp of the block may be read from the memory.

In operation S806, the read level is changed, and the fail bit count of the selected memory page in the block with the minimum timestamp is read.

Here, the read operation is performed on the selected memory cell in the selected block, and the selected memory cell may refer to all memory cells included in one memory page in the selected block.

Taking TLC as an example for illustration, the read voltage, for example, the seventh read voltage Vrd_p7, is selected, and when the read operation is performed on the memory, the raw data (that is, the data obtained after randomization processing) in the memory needs to be read; the raw data is de-randomized to obtain the host data; the error checking and correcting (ECC) is used for decoding processing to obtain the initial fail bit count; the read voltage is readjusted (for example, the seventh read voltage Vrd_p7 is moved to the left, or the seventh read voltage Vrd_p7 is decreased), and the read operation is re-performed on the memory by using the new read voltage to obtain a new fail bit count; the read operation is repeatedly performed multiple times until the minimum value of the fail bit count, that is, the minimum fail bit count, is found.

In operation S807, a read offset corresponding to a minimum fail bit count is obtained.

Here, the difference between the read voltage corresponding to the initial fail bit count and the read voltage corresponding to the minimum fail bit count is determined as the read offset.

Here, there is a mapping relationship between the read offset and the equivalent retention duration, and as the equivalent retention duration increases, the absolute value of the read offset increases. For the threshold voltage distribution curve, as the equivalent retention duration increases, the offset degree of the threshold voltage distribution curve increases, and more specifically, the offset degree of the threshold voltage distribution curve towards the left increases. It should be noted that the positive and negative values of the read offset represent the offset direction of the read voltage. For example, the read offset being a negative value represents the read voltage being offset to the left, that is, the read voltage is decreased; and the read offset being a positive value represents the read voltage being offset to the right, that is, the read voltage is increased.

In operation S808, the equivalent retention duration and the equivalent power off duration are obtained through the preset mapping table between the read offset and the equivalent retention duration.

Here, the preset mapping table between the read offset and the equivalent retention duration may be pre-characterized, so that the preset mapping table is looked up according to the read offset, and the equivalent retention duration may be determined. It should be noted that both the program-erase count and the equivalent retention duration may affect the read offset, where in the case that the program-erase count is the same, the larger the equivalent retention duration is, the larger the absolute value of the read offset is; and in the case that the equivalent retention duration is the same, the larger the program-erase count is, the larger the absolute value of the read offset is.

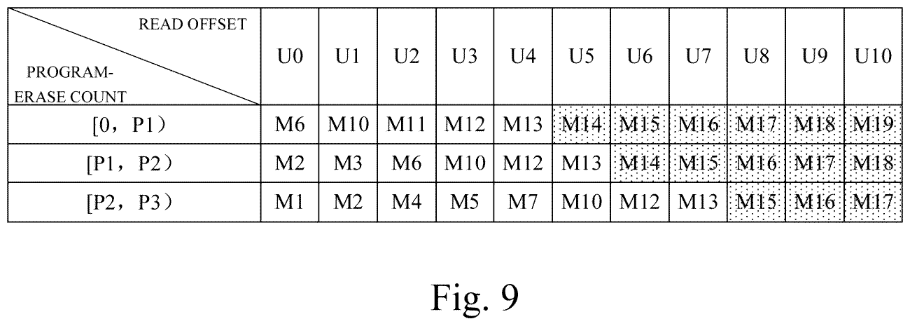

Referring to FIG. 9, FIG. 9 is a preset mapping table between read offsets and equivalent retention durations at different erase range intervals according to some examples. As shown in FIG. 9, the horizontal axis illustrates the read offsets, the absolute values of the read offsets satisfy |U|<|U1|<|U2|<|U3|<|U4|<|U5|<|U6|<|U7|<|U8|<|U9|<|U10|, that is, the absolute values of the read offsets gradually increase from left to right. The vertical axis illustrates erase count range intervals, the program-erase counts, where 0<P1<P2<P3, that is, the erase count gradually increases from top to bottom. In addition, the larger the number in the equivalent retention duration is, the larger the equivalent retention duration is, e.g., M1<M2< . . . <M19.

Here, in the case that the program-erase count is the same, for each row illustrated in FIG. 9, as the equivalent retention duration increases, the absolute value of the read offset increases. As shown in FIG. 9, the equivalent retention durations in the first row satisfy M6<M10<M11<M12<M13<M14<M15<M16<M17<M18<M19, the equivalent retention durations in the second row satisfy M2<M3<M6<M10<M12<M13<M14<M15<M16<M17<M18, and the equivalent retention durations in the third row satisfy M1<M2<M4<M5<M7<M10<M12<M13<M15<M16<M17.

Here, in the case that the equivalent retention duration is the same, the larger the program-erase count is, the larger the absolute value of the read offset is. In other words, in the case that the absolute value of the read offset is the same, for each column illustrated in FIG. 9, as the program-erase count increases, the equivalent retention duration decreases. As shown in FIG. 9, the equivalent retention durations in the first column satisfy M6>M2>M1, the equivalent retention durations in the second column satisfy M10>M3>M2, the equivalent retention durations in the third column satisfy M11>M6>M4, the equivalent retention durations in the fourth column satisfy M12>M10>M5, the equivalent retention durations in the fifth column satisfy M13>M12>M7, the equivalent retention durations in the sixth column satisfy M14>M13>M10, the equivalent retention durations in the seventh column satisfy M15>M14>M12, the equivalent retention durations in the eighth column satisfy M16>M15>M13, the equivalent retention durations in the ninth column satisfy M17>M16>M15, the equivalent retention durations in the tenth column satisfy M18>M17>M16, and the equivalent retention durations in the eleventh column satisfy M19>M18>M17.

Here, the equivalent power off duration of the memory system is equal to the equivalent retention duration of the selected block minus the initial timestamp of the selected block (that is, the initial equivalent retention duration of the selected block). For the selected block, the preset mapping table is looked up according to the read offset, and the equivalent retention duration of the selected block is determined; and according to the initial timestamp of the selected block and the equivalent retention duration of the selected block, the equivalent power off duration of the memory system is calculated.

In operation S809, the initial timestamp of the block is updated by increasing the equivalent power off duration.

Here, the updated timestamp of the block is determined according to the initial timestamp of the block and the equivalent power off duration of the memory system. The equivalent retention duration of the stored data in the block includes an initial equivalent retention duration before the memory system is powered off and an equivalent power off duration after the memory system is powered off and before the memory system is re-powered on, that is, the equivalent retention duration of the block is equal to the initial timestamp of the block (e.g., the initial equivalent retention duration of the block) plus the equivalent power off duration of the memory system.

In operation S810, the read voltage is determined according to the updated timestamp of the block.

In the above technical solution, in the process of determining the equivalent power off duration by reading the fail bit count of the selected memory cell in the selected block, the read voltage needs to be adjusted multiple times, and the fail bit count is obtained after the decoding processing. This process of determining the equivalent power off duration needs to take a longer time. In addition, for the memory system at the end of lifetime, the fail bit count may not be obtained, resulting in inaccurate determined equivalent power off duration.

In view of this, implementations of the present disclosure provide a memory system, an operating method thereof, and a computer readable storage medium.

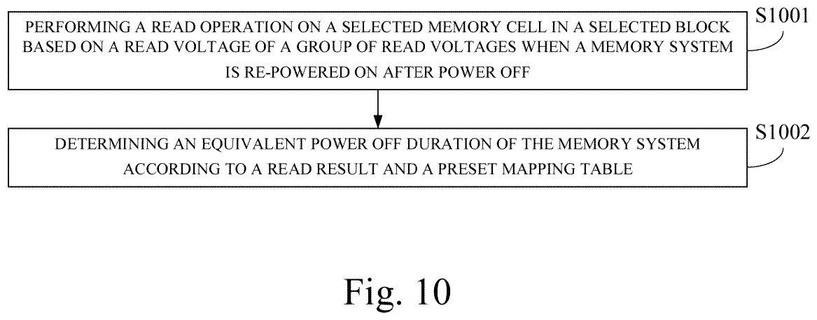

Referring to FIG. 10, FIG. 10 is a schematic flowchart of a method for operating a memory system according to an implementation of the present disclosure. As shown in FIG. 10, in combination with FIG. 1, an implementation of the present disclosure provides a method for operating a memory system, where the memory system 102 includes a memory 104 and a controller 106 coupled to the memory 104, the memory includes a plurality of blocks, each block includes a plurality of memory cells, each memory cell is configured to store one of a plurality of memory states, the plurality of memory states correspond to a group of read voltages, and a read voltage in the group of read voltages is configured to distinguish different memory states. The operation method includes: operation S1001 of performing a read operation on a selected memory cell in a selected block based on a read voltage of the group of read voltages when the memory system is re-powered on after power off; and operation S1002 of determining an equivalent power off duration of the memory system according to a read result and a preset mapping table.

As compared to determining the equivalent power off duration of the memory system by adjusting the read voltage multiple times, in the implementation of the present disclosure, the SLR operation may be utilized for quickly obtaining the state information of the memory cell, which may save time. In addition, by combining it with a preset mapping table which is pre-characterized, the equivalent power off duration of the memory system is determined, and the operation is more flexible and simple. In addition, as compared to obtaining the fail bit count by decoding processing, in the implementations of the present disclosure, it is not necessary that the fail bit count is obtained by decoding processing, and instead the state information of the memory cell can also be obtained at the end of lifetime of the memory system in the case of decoding failure, so as to obtain the equivalent power off duration of the memory system, and thus the implementations of the present disclosure have a broader application range. Further, in the implementation of the present disclosure, the equivalent retention duration of the data stored in the block is determined according to the equivalent power off duration; and in turn the read voltage during the subsequent read operation is determined according to the equivalent retention duration, thereby satisfying the quality of service requirement for the subsequent one-shot read pass of the memory system.

Here, each memory cell may be configured to store one of a plurality of memory states, the plurality of memory states correspond to a group of read voltages, and a read voltages in the group of read voltages is configured to distinguish different memory states. For example, the memory cell may be configured as TLC, and each memory cell of the TLC may be configured to store one of 8 memory states, the 8 memory states correspond to a group of read voltages, the group of read voltages includes 7 read voltages, and 7 read voltages may be configured to distinguish 8 memory states. In the implementations of the present disclosure, the number of read voltages included in the group of read voltages is not specifically limited, and each memory cell may be configured as SLC, MLC, TLC or QLC.

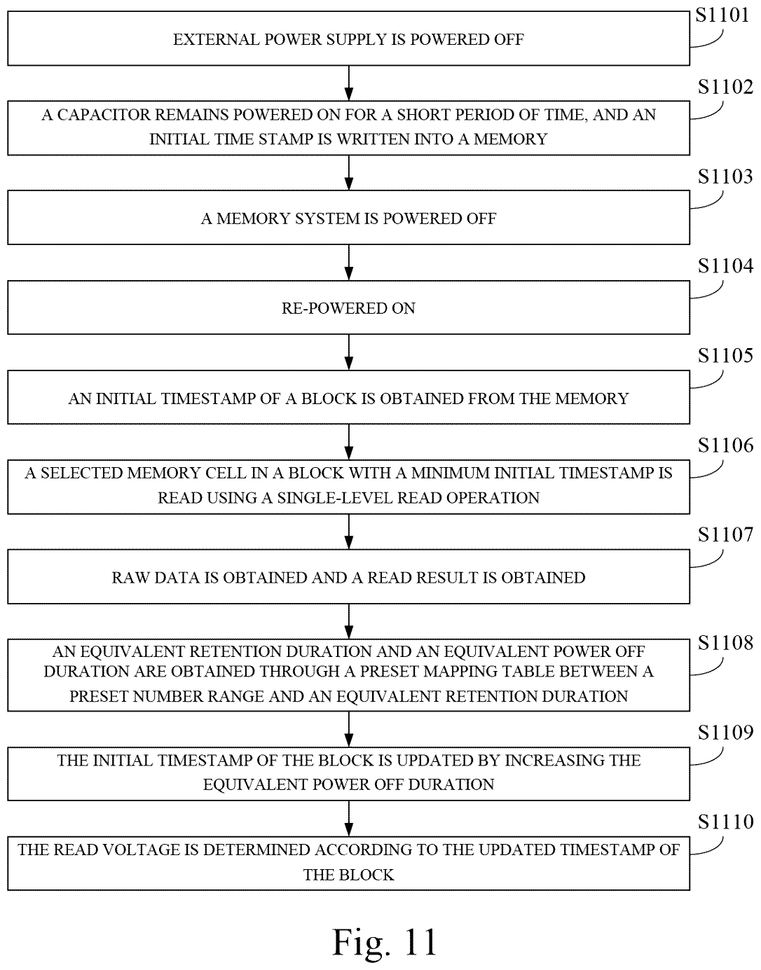

FIG. 11 is a flowchart of predicting an equivalent power off duration according to an implementation of the present disclosure. As shown in FIG. 11, in operation S1101, the external power supply is powered off, that is, the external power supply is turned off.

In operation S1102, the capacitor remains powered on for a short period of time, and the initial time stamp is written to the memory.

Here, after the external power supply is powered off and before the memory system is powered off, the capacitor may also remain powered on for a short period of time during which the initial timestamp of the block may be written to the memory. The initial timestamp refers to the equivalent retention duration of the data stored in the block before the memory system is powered off. Of course, the initial timestamp may also be referred to as an initial equivalent retention duration, and the initial equivalent retention duration is determined based on the temperature and the initial physical retention duration.

Here, writing the initial timestamp to the memory after the external power supply is powered off and before the memory system is powered off is not a necessary operation. In some implementations, the timestamp of the block may be globally updated with a certain update frequency (for example, per 30 minutes), and the updated timestamp of the block is written to the memory; where the last updated timestamp of the memory system before power off is used as the initial timestamp of the block.

Here, the initial timestamp refers to the equivalent retention duration of the data stored in the block before the memory system is powered off, therefore only the blocks to which the data is written have initial timestamps, such as open blocks and close blocks. That is, the blocks to which the data is not written do not have initial timestamps. For example, timing may start from writing the first page of data to the block, and the initial timestamp is recorded; of course, timing may also start from the block be written and full of data, and the initial timestamp is recorded.

In operation S1103, the memory system is powered off, that is, the memory system is turned off.

Here, the memory system may determine that the memory system is about to be powered off by, for example, detecting a voltage drop, so the initial timestamp may be written to the memory before the memory system is powered off.

In operation S1104, re-powered on is performed, that is, the external power supply is re-powered on and the memory system is re-powered on.

In some implementations, the operation method further includes: obtaining an initial timestamp of the block when the memory system is re-powered on after power off.

In operation S1105, an initial timestamp of the block is obtained from the memory.

Here, if the initial timestamp of the block has been written to the memory before the memory system is powered off, the initial timestamp of the block may be read from the memory; and if the initial timestamp of the block is not written to the memory before the memory system is powered off, the last updated timestamp of the memory system before power off may be read from the memory.

In some implementations, after obtaining an initial timestamp of the block when the memory system is re-powered on after power off, the operation method further includes: determining the close block having the minimum initial timestamp as the selected block according to the initial timestamp of the block.

Here, it may be considered that the close block is determined as the selected block. Since all the memory cells in the close block have been programmed, it is possible to avoid the error caused by selecting an open block with a different programming degree (that is, the number of programmed memory cells in the open blocks is different) as the selected block.

Further, the close block with the minimum initial timestamp (that is, the latest close block) may be determined as the selected block. Because the equivalent retention duration of the selected block is equal to the initial timestamp of the selected block (that is, the initial equivalent retention duration of the selected block) plus the equivalent power off duration of the memory system, the close block with the minimum initial timestamp is selected as the selected block, and in this case, the proportion of the initial timestamp in the equivalent retention duration of the selected block is smaller and the proportion of the equivalent power off duration is larger, so that the error of calculating the equivalent power off duration of the memory system is reduced.

In addition, secondary factors such as read count and write temperature difference stress may also be considered when determining the selected block.

In operation S1106, the selected memory cell in the block with the minimum initial timestamp is read by using a single-level read (SLR) operation.

Here, a read operation is performed on the selected memory cell in the selected block, and the selected memory cell may refer to all memory cells included in one memory page in the selected block.

In operation S1107, raw data is obtained and a read result is obtained.

It should be noted that, for a TLC that has been performed a program operation, and in which each memory cell may store three bits of data, the SLR operation cannot read the actual stored data in each memory cell. However, the SLR operation can still be used to represent that the threshold voltage distribution curve offsets with the change in the equivalent retention duration, and as the equivalent retention duration increases, the offset degree of the threshold voltage distribution curve increases. As the equivalent retention duration increases, the threshold voltage distribution curve shifts to the left, at which case the count value of “0” decreases and the count value of “1” increases.

Here, the count value distribution of the first type of memory cells and the second type of memory cells may be considered as a randomization distribution eigenvalue, which is a read result of the SLR operation. In other words, the count value of “0” or the count value of “1” may be used as the read result.

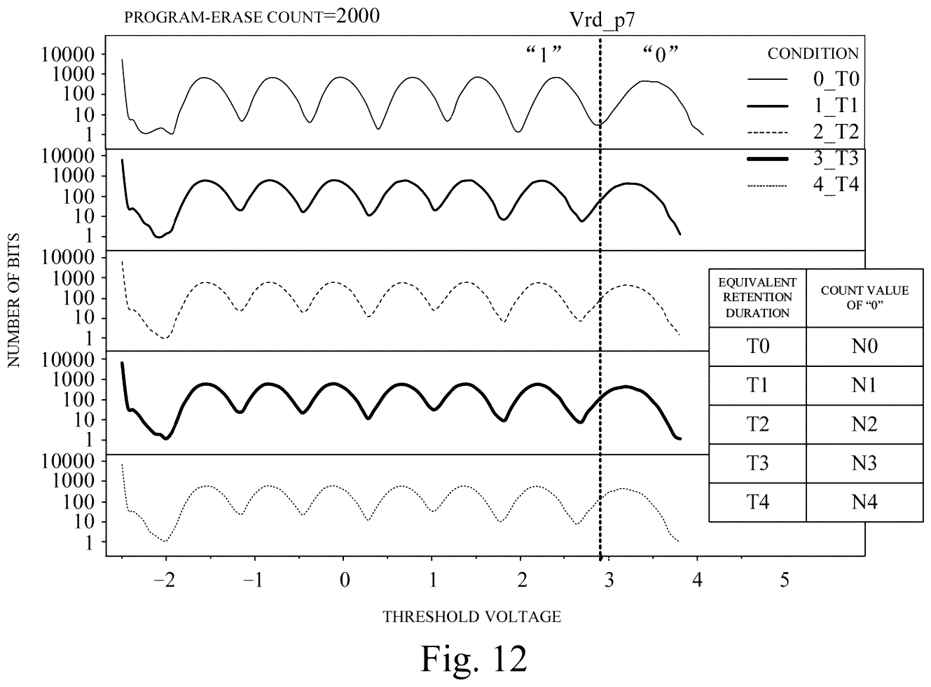

Referring to FIG. 12, FIG. 12 is a threshold voltage distribution diagram after different equivalent retention durations according to an implementation of the present disclosure. As shown in FIG. 12, taking TLC as an example for description, the horizontal coordinate represents the threshold voltage, the vertical coordinate represents the number of bits, and the program-erase count of the memory cell is 2000. The read voltage, such as the seventh read voltage Vrd_p7, is selected to perform the SLR operation, and the memory cells targeted by the SLR operation are divided into two types. The threshold voltage of the first type of memory cells is less than the seventh read voltage Vrd_p7, and the data stored in the first type of memory cells may be regarded as “1”; the threshold voltage of the second type of memory cells is greater than or equal to the seventh read voltage Vrd_p7, and the data stored in the second type of memory cells may be regarded as “0”. As also shown in FIG. 7, the number of memory cells of the first type is a sum of the numbers of memory cells having an erased state P0 and a first programmed state P1 to a sixth programmed state P6, and the number of memory cells of the second type is the number of memory cells having a seventh programmed state P7.

As shown in FIG. 12, there is a mapping relationship between the count values of “0” and the equivalent retention durations, the count values of “0” satisfy N0>N1>N2>N3>N4, and the equivalent retention durations satisfy T0<T1<T2<T3<T4. That is, as the equivalent retention duration increases, the count value of “0” decreases.

In operation S1108, an equivalent retention duration and an equivalent power off duration are obtained by a preset mapping table between a preset number range and an equivalent retention duration.

Here, the preset mapping table between the preset number range and the equivalent retention duration may be pre-characterized, so that the preset mapping table is looked up according to the read result, and the equivalent retention duration may be determined. It should be noted that the program-erase count and the equivalent retention duration may both affect the read result, where in the case that the program-erase count is the same, the larger the equivalent retention duration is, the smaller the count value of “0” is; and in the case that the equivalent retention duration is the same, the larger the program-erase count is, the smaller the count value of “0” is.

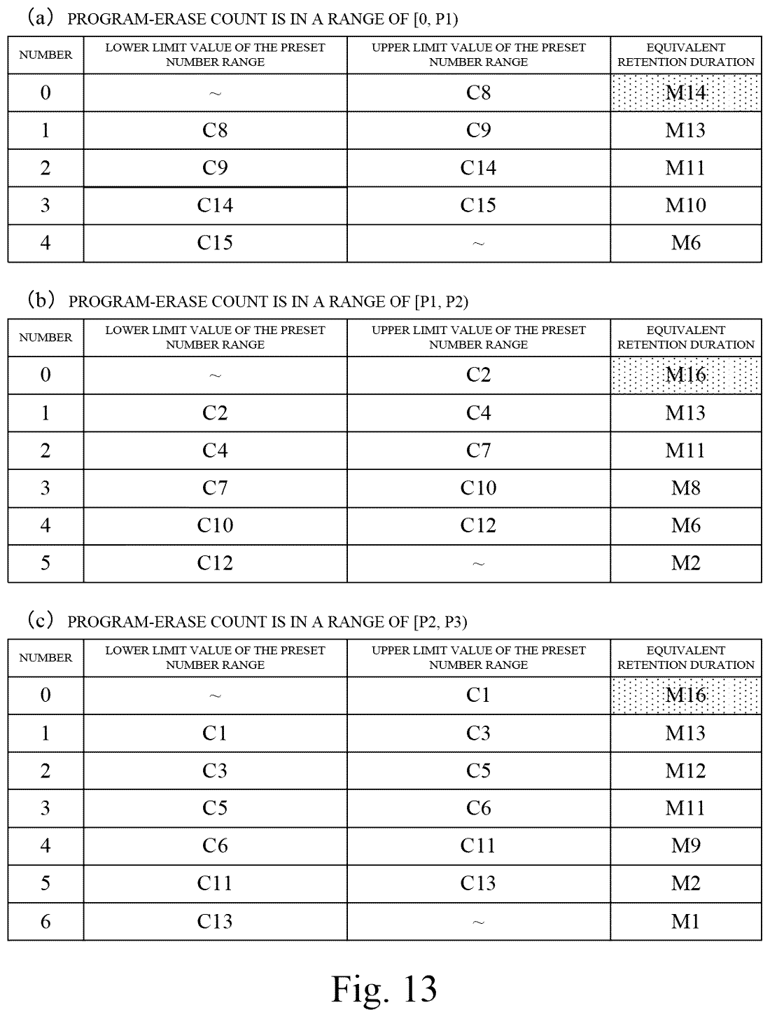

Referring to FIG. 13, FIG. 13 is a preset mapping table between a preset number range and an equivalent retention duration at different erase range intervals according to an implementation of the present disclosure. In FIG. 13, diagrams (a), (b), and (c) each show a preset mapping table where program-erase counts are in ranges of [0, P1), [P1, P2) and [P2, P3], respectively, where 0<P1<P2<P3. As shown in diagram (a) in FIG. 13, the horizontal axis shows the sequence number, the lower limit value of the preset number range, the upper limit value of the preset number range, and the equivalent retention duration respectively. The equivalent retention durations satisfy M6<M10<M11<M13<M14, that is, from bottom to top, the equivalent retention duration gradually increases; and for the lower and upper limit values of the preset number range, the count values of “0” satisfy C15>C14>C9>C8. As shown in diagram (b) in FIG. 13, the equivalent retention durations satisfy M2<M6<M8<M11<M13<M16, that is, from bottom to top, the equivalent retention duration gradually increases; and for the lower and upper limit values of the preset number range, the count values of “0” satisfy C12>C10>C7>C4>C2. As shown in diagram (c) in FIG. 13, the equivalent retention durations satisfy M1<M2<M9<M11<M12<M13<M16, that is, from bottom to top, the equivalent retention duration gradually increases; and for the lower and upper limit values of the preset number range, the count values of “0” satisfy C13>C11>C6>C5>C3>C1. The larger the number in the upper and lower limit values of the preset number range, the larger the count value of “0” is, that is, C15>C14> . . . >C1.

Here, it is contemplated that both the program-erase count and the equivalent retention duration may affect the count value of “0”. In some implementations, operation S1002 includes: determining an erase range interval in which the selected block is according to the erase count of the selected block, for example, determining which of the preset mapping tables of the diagrams (a), (b) and (c) in FIG. 13 is used according to the program-erase count of the selected block; and determining the equivalent retention duration of the selected block according to the read result and the preset mapping table corresponding to the erase range interval in which the selected block is.

In some implementations, operation S1002 includes: determining an equivalent retention duration of the selected block according to the read result and the preset mapping table, where the read result includes a number of memory cells having a threshold voltage greater than or equal to the read voltage and a number of memory cells having a threshold voltage less than the read voltage, the preset mapping table includes a mapping relationship between a preset number range and an equivalent retention duration, and the equivalent retention duration is determined based on a temperature and a physical retention duration; and determining an equivalent power off duration of the memory system according to a difference between the equivalent retention duration of the selected block and the initial timestamp of the selected block.

For example, according to the program-erase count of the selected block, for example, the program-erase count of the selected block within the range [0, P1), it is determined that the preset mapping table of diagram (a) in FIG. 13 is used; and according to the count value of “0” in the read result, for example, it is determined that the count value of “0” is within the preset number range of from C9 to C14 in the preset mapping table of diagram (a) in FIG. 13, and according to the preset number range of from C9 to C14, the corresponding equivalent retention duration M11 is determined.

Here, the equivalent power off duration of the memory system is determined according to the difference between the equivalent retention duration of the selected block and the initial timestamp of the selected block. If the difference between the equivalent retention duration of the selected block and the initial timestamp of the selected block is greater than or equal to 0, the equivalent power off duration of the memory system is equal to the equivalent retention duration of the selected block minus the initial timestamp of the selected block (that is, the initial equivalent retention duration of the selected block); and if the difference between the equivalent retention duration of the selected block and the initial timestamp of the selected block is less than 0, the equivalent power off duration of the memory system is 0. Of course, the difference between the equivalent retention duration of the selected block and the initial timestamp of the selected block being less than 0 may be caused by a calculation error.

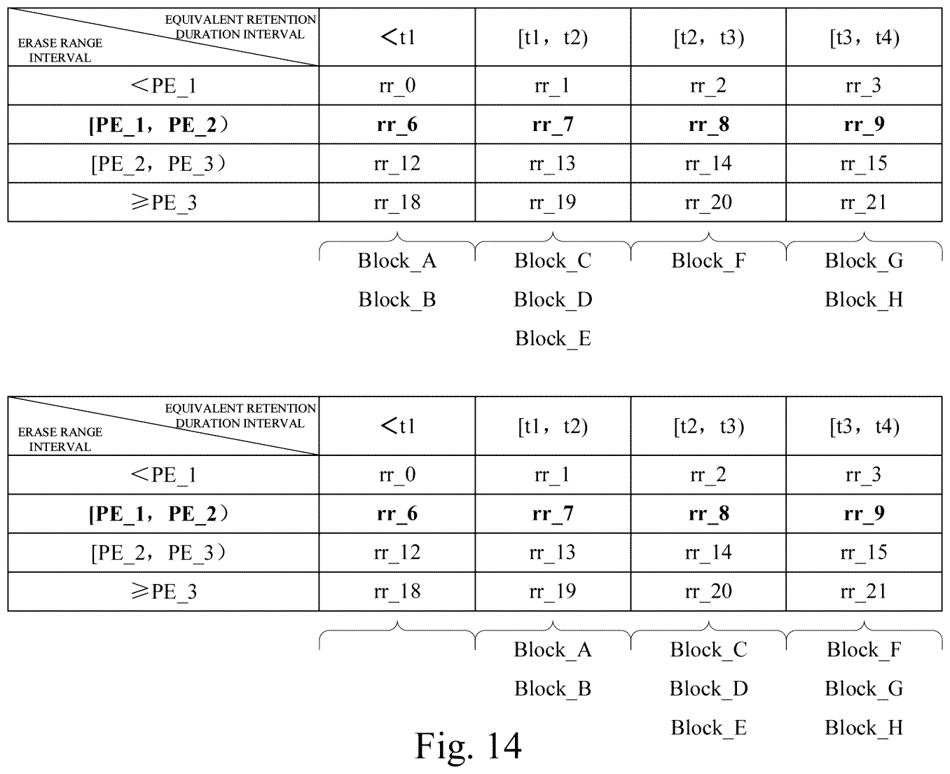

Referring to FIG. 14, FIG. 14 is a schematic diagram of updating an initial timestamp of a block according to an implementation of the present disclosure. As shown in FIG. 14, the horizontal axis illustrates the equivalent retention duration interval, where the equivalent retention durations satisfy t1<t2<t3<t4; and the vertical axis illustrates the erase range interval, where the program-erase counts satisfy PE_1<PE_2<PE_3. The block is classified according to the equivalent retention duration and the program-erase count, where the equivalent retention duration of the blocks Block_A and Block_B is within the range of <t1 and the program-erase count is within the range of [PE_1, PE_2]; the equivalent retention duration of the blocks Block_C, Block_D and Block_E is within the range of [t1, t2) and the program-erase count is within the range of [PE_1, PE_2]; the equivalent retention duration of the block Block_F is in the range of [t2, t3] and the program-erase count is within the range of [PE_1, PE_2]; and the equivalent retention duration of the blocks Block_G and Block_H is in the range of [t3, t4] and the program-erase count is within [PE_1, PE_2].

In operation S1109, the initial timestamp of the block is updated by increasing the equivalent power off duration.

In operation S1110, the read voltage is determined according to the updated timestamp of the block.

In some implementations, after the operation S1002, the operation method further includes: updating the initial timestamp of the block according to the initial timestamp and the equivalent power off duration of the block, where the updated timestamp of the block (that is, the equivalent retention duration of the block) is equal to the initial timestamp of the block (that is, the initial equivalent retention duration of the block) plus the equivalent power off duration of the memory system; and determining the read voltage when the read operation is performed on the block according to the updated timestamp of the block.

In some implementations, the determining the read voltage when the read operation is performed on the block according to the updated timestamp of the block includes: determining an equivalent retention duration interval in which the block is according to the updated timestamp of the block; and determining the read voltage when the read operation is performed on the block according to the equivalent retention duration interval in which the block is.

As shown in FIG. 14, based on the initial timestamp of the block, the equivalent power off duration is added to obtain the updated timestamp of the block, and therefore, the block may be re-classified according to the updated timestamp of the block. The block is classified according to the equivalent retention duration and the program-erase count, where the equivalent retention duration of the blocks Block_A and Block_B is increased, and is in the range of [t1, t2]; the equivalent retention duration of the blocks Block_C, Block_D and Block_E is increased, and is within the range of [t2, t3]; the equivalent retention duration of the block Block_F is increased, and is within the range of [t3, t4]; and the equivalent retention duration of the blocks Block_G and Block_H is increased, but is still within the range of [t3, t4]. In other words, after the equivalent retention duration is increased, the equivalent retention duration intervals, in which the blocks Block_A, Block_B, Block_C, Block_D, Block_E, and Block_F are, are changed, and therefore, the read voltage when the read operation is performed on the block is re-determined according to the updated timestamp of the block. After the equivalent retention duration is increased, there is no change in the equivalent retention duration interval in which the blocks Block_G and Block_H are, and therefore, the read voltage when the read operation is performed on the block is re-determined to be unchanged according to the updated timestamp of the block.

In some implementations, the operation method further includes: if the updated timestamp of the block is greater than or equal to the equivalent retention duration threshold, performing a refresh operation on the block.

Here, if the updated timestamp of the block is greater than or equal to the equivalent retention duration threshold, it is generally considered that the equivalent retention duration of the data stored in these blocks is too long, and the reliability of the data stored in the blocks is difficult to guaranteed. Therefore, a refresh operation needs to be performed on the blocks. The refresh operation may include moving the data stored in a block to another block, and performing an erase operation on the block. The specific values of the equivalent retention duration threshold are not particularly limited in the implementations of the present disclosure, and those skilled in the art may flexibly select it according to actual conditions.

It should be noted that FIG. 9 illustrates that a square background where the equivalent retention duration is >M14 has a padding pattern, which indicates that when the equivalent retention duration of the block is >M14, a refresh operation may be performed on the block. Similarly, diagram (a) in FIG. 13 shows that a square background with equivalent retention duration M14 has a padding pattern, and diagram (b) in FIG. 13 and diagram (c) in FIG. 13 show square background with equivalent retention duration M16 have padding patterns.

In the implementations of the present disclosure, after the memory system is re-powered on, it is unnecessary to adjust the read voltage multiple times, and only one read voltage in the group of read voltages needs to be used to perform the SLR operation, thereby saving time. In addition, in the implementations of the present disclosure, the raw data is read, and the equivalent power off duration may be determined by using the randomized distribution eigenvalues of “0” and “1” in the raw data, without performing de-randomization processing and decoding processing. In addition, in the implementation of the present disclosure, the equivalent power off duration is configured to compensate and update the initial equivalent retention duration of the block, and the read voltage when the subsequent read operation is performed is re-determined.

The preset mapping table obtained by pre-characterization is stored in the memory, and may be directly called if required. The process of obtaining the preset mapping table by characterization will be described in detail below.

In some implementations, the operation method further includes: reading a plurality of reference samples, and determining a read result of each of the reference samples at different equivalent retention durations; and determining a preset number range at the same equivalent retention duration according to read results of the plurality of reference samples at the same equivalent retention duration, and determining a mapping relationship between the preset number range and the equivalent retention duration as the preset mapping table.

Here, the preset mapping table includes a mapping relationship between a preset number range and an equivalent retention duration. For example, a plurality of reference samples are read, and a count value of “0” (or a count value of “1”) of each reference sample at an equivalent retention duration such as 1 day, 5 days, 6 days, 10 days and 15 days is determined; and a minimum value and a maximum value of the count values of “0” at the equivalent retention duration of 1 day (or 5 days, 6 days, 10 days, 15 days) are determined according to the count values of “0” of the plurality of reference samples at the equivalent retention duration of 1 day (or 5 days, 6 days, 10 days, 15 days), where the minimum value of the count values of “0” may be used as the lower limit value of the preset number range, and the maximum value of the count values of “0” may be used as the upper limit value of the preset number range. As such, the mapping relationship between the preset number range and the equivalent retention duration may be obtained as the preset mapping table.

In some implementations, the plurality of reference samples are in different erase range intervals; the preset number range of the reference samples in different erase range intervals at the same equivalent retention duration is determined according to read results of the reference samples in different erase range intervals at the same equivalent retention duration; and a mapping relationship between the preset number range of the reference samples in different erase range intervals and the equivalent retention duration is determined as preset mapping table, where a number of the erase range intervals and a number of the preset mapping tables are the same.

Here, both program-erase counts and equivalent retention durations may affect the read results. Therefore, the preset mapping table between the preset number range and the equivalent retention duration is obtained under the condition of the same erase range interval. Different erase range intervals correspond to different preset mapping tables.

For a memory system using the operation method provided by the implementations of the present disclosure, the command CMD waveform is detected by using a logic analyzer (LA) when re-powered on after power off. Compared with adjusting read voltages multiple times when performing the read operation using the TLC mode, in the implementation of the present disclosure, since the SLR operation is used, the time is saved, and the time for the read performance drop is shorter.

As shown in FIG. 1, an implementation of the present disclosure provides a memory system, the memory system 102 includes a memory 104 and a controller 106 coupled to the memory 104, where the memory includes a plurality of blocks, each of the blocks includes a plurality of memory cells, each of the memory cells is configured to store one of a plurality of memory states, the plurality of memory states correspond to a group of read voltages, a read voltage of the group of read voltages is configured to distinguish different memory states, and the controller 106 is configured to: perform a read operation on a selected memory cell in a selected block based on the read voltage of the group of read voltages when the memory system is re-powered on after power off; and determine an equivalent power off duration of the memory system according to a read result and a preset mapping table.

In some implementations, the controller 106 is further configured to: obtain an initial timestamp of the block when the memory system is re-powered on after power off; where the initial timestamp is configured to indicate an initial equivalent retention duration of the block before power off, and the initial equivalent retention duration is determined based on a temperature and an initial physical retention duration.

In some implementations, the controller 106 is configured to: determine an equivalent retention duration of the selected block according to the read result and the preset mapping table, where the read result includes a number of memory cells having a threshold voltage greater than or equal to the read voltage and a number of memory cells having a threshold voltage less than the read voltage, the preset mapping table includes a mapping relationship between a preset number range and an equivalent retention duration, and the equivalent retention duration is determined based on a temperature and a physical retention duration; and determine an equivalent power off duration of the memory system according to a difference between the equivalent retention duration of the selected block and the initial timestamp of the selected block, where the equivalent power off duration is determined based on a temperature and a physical power off duration.

In some implementations, the controller 106 is further configured to: update the initial timestamp of the block according to the initial timestamp of the block and the equivalent power off duration; and determine the read voltage when the read operation is performed on the block according to the updated timestamp of the block, where the updated timestamp is configured to indicate a sum of an initial equivalent retention duration of the block before power off and the equivalent power off duration.

In some implementations, the controller 106 is configured to: determine an equivalent retention duration interval, in which the block is, according to the updated timestamp of the block; and determine the read voltage when the read operation is performed on the block according to the equivalent retention duration interval, in which the block is.

In some implementations, the controller 106 is further configured to: if the updated timestamp of the block is greater than or equal to the equivalent retention duration threshold, perform a refresh operation on the block.

In some implementations, the controller 106 is further configured to: read a plurality of reference samples, and determine a read result of each of the reference samples at different equivalent retention durations; and determine a preset number range at the same equivalent retention duration according to read results of the plurality of reference samples at the same equivalent retention duration, and determine a mapping relationship between the preset number range and the equivalent retention duration as the preset mapping table.

In some implementations, the plurality of reference samples are in different erase range intervals; and the controller 106 is configured to: determine the preset number range of the reference samples in different erase range intervals at the same equivalent retention duration according to read results of the reference samples in different erase range intervals at the same equivalent retention duration, and determine a mapping relationship between the preset number range of the reference samples in different erase range intervals and the equivalent retention duration as the preset mapping table, where a number of the erase range intervals and a number of the preset mapping tables are the same.

In some implementations, the controller 106 is configured to: determine an erase range interval, in which the selected block is, according to erase count of the selected block; and determine the equivalent retention duration of the selected block according to the read result and the preset mapping table corresponding to the erase range interval, in which the selected block is.

In some implementations, the controller 106 is further configured to: determine a close block having a minimum initial timestamp as the selected block according to the initial timestamp of the block.

An implementation of the present disclosure provides a computer-readable storage medium, the computer-readable storage medium stores a computer program, and when the computer program is executed, the operation method of the memory system in the foregoing technical solution may be implemented.

In the implementations of the present disclosure, the computer-readable storage medium may include a random access memory (RAM), an internal storage, a read-only memory (ROM), an electrically programmable ROM, an electrically erasable programmable ROM, a register, a hard disk, a removable magnetic disk, a compact disk read-only memory (CD-ROM), or a medium in any other form for storing a program code as known in the art.

The implementations of the present disclosure provide a memory system and an operation method thereof, and a computer readable storage medium. In the implementations of the present disclosure, a read operation is performed on a selected memory cell based on a read voltage of a group of read voltages, and an equivalent power off duration of the memory system is determined according to a read result and a preset mapping table. In this way, the state information of the memory cell can be quickly obtained by using a single-level read operation, and by combining it with a preset mapping table which is pre-characterized, the equivalent power off duration of the memory system is determined; therefore, it is beneficial to determine the equivalent retention duration of data stored in the block, and it is in turn beneficial to determine the read voltage when the read operation is subsequently performed, thereby satisfying the quality of service requirement for the subsequent one-shot read pass of the memory system.

It should be understood that reference to “one implementation” or “an implementation” throughout the specification means that specific features, structures, or characteristics related to the implementation may be included in at least one implementation of the present disclosure. Thus, the occurrence of “in one implementation” or “in an implementation” throughout the specification doesn't necessarily refer to the same implementation. Further, these particular features, structures, or characteristics may be incorporated in one or more implementations in any suitable manner. It should be understood that, in various implementations of the present disclosure, the sequence numbers of the foregoing processes do not mean the order of execution, and the execution sequence of each process should be determined by its function and internal logic, and should not constitute any limitation on the process of the implementations of the present disclosure. The foregoing sequence numbers of the implementations of the present disclosure are merely for description, and do not represent the advantages of the implementations.

In view of this, implementations of the present disclosure provide a memory system, an operating method thereof, and a computer readable storage medium.

In order to achieve the above object, the technical solution of the present disclosure is implemented as follows.

According to a first aspect, an implementation of the present disclosure provides an operation method of a memory system, where the memory system includes a memory and a controller coupled to the memory, the memory includes a plurality of blocks, each of the blocks includes a plurality of memory cells, each of the memory cells is configured to store one of a plurality of memory states, the plurality of memory states correspond to a group of read voltages, and a read voltage of the group of read voltages is configured to distinguish different memory states, the operation method includes: performing a read operation on a selected memory cell in a selected block based on the read voltage of the group of read voltages when the memory system is re-powered on after power off; and determining an equivalent power off duration of the memory system according to a read result and a preset mapping table.

In some implementations, the operation method further includes: obtaining an initial timestamp of the block when the memory system is re-powered on after power off, where the initial timestamp is configured to indicate an initial equivalent retention duration of the block before power off, and the initial equivalent retention duration is determined based on a temperature and an initial physical retention duration.

In some implementations, the determining the equivalent power off duration of the memory system according to the read result and the preset mapping table includes: determining an equivalent retention duration of the selected block according to the read result and the preset mapping table, where the read result includes a number of memory cells having a threshold voltage greater than or equal to the read voltage and a number of memory cells having a threshold voltage less than the read voltage, the preset mapping table includes a mapping relationship between a preset number range and an equivalent retention duration, and the equivalent retention duration is determined based on a temperature and a physical retention duration; and determining the equivalent power off duration of the memory system according to a difference between the equivalent retention duration of the selected block and the initial timestamp of the selected block, where the equivalent power off duration is determined based on a temperature and a physical power off duration.

In some implementations, after determining the equivalent power off duration of the memory system according to the read result and the preset mapping table, the operation method further includes: updating the initial timestamp of the block according to the initial timestamp of the block and the equivalent power off duration; and determining the read voltage when the read operation is performed on the block according to the updated timestamp of the block, where the updated timestamp is configured to indicate a sum of the initial equivalent retention duration of the block before power off and the equivalent power off duration.

In some implementations, the determining the read voltage when the read operation is performed on the block according to the updated timestamp of the block includes: determining an equivalent retention duration interval, in which the block is, according to the updated timestamp of the block; and determining the read voltage when the read operation is performed on the block according to the equivalent retention duration interval, in which the block is.

In some implementations, the operation method further includes: if the updated timestamp of the block is greater than or equal to an equivalent retention duration threshold, performing a refresh operation on the block.

In some implementations, the operation method further includes: reading a plurality of reference samples, and determining a read result of each of the reference samples at different equivalent retention durations; and determining a preset number range at the same equivalent retention duration according to the read results of the plurality of reference samples at the same equivalent retention duration, and determining a mapping relationship between the preset number range and the equivalent retention duration as the preset mapping table.

In some implementations, the plurality of reference samples are in different erase range intervals; the determining the preset number range at the same equivalent retention duration according to the read results of the plurality of reference samples at the same equivalent retention duration, and determining the mapping relationship between the preset number range and the equivalent retention duration as the preset mapping table includes: determining the preset number range of the reference samples in the different erase range intervals at the same equivalent retention duration according to the read results of the reference samples in the different erase range intervals at the same equivalent retention duration, and determining a mapping relationship between the preset number range of the reference samples in the different erase range intervals and the equivalent retention duration as the preset mapping table, where a number of the erase range intervals and a number of the preset mapping tables are the same.

In some implementations, the determining the equivalent power off duration of the memory system according to the read result and the preset mapping table includes: determining the erasing range interval, in which the selected block is, according to erasing count of the selected block; and determining the equivalent retention duration of the selected block according to the read result and the preset mapping table corresponding to the erasing range interval, in which the selected block is.

In some implementations, after obtaining the initial timestamp of the block after the memory system is re-powered on after power off, the operation method further includes: determining a close block having a minimum initial timestamp as the selected block according to the initial timestamp of the block.

According to a second aspect, an implementation of the present disclosure provides a memory system, the memory system includes a memory and a controller coupled to the memory, the memory includes a plurality of blocks, each of the blocks includes a plurality of memory cells, each of the memory cells is configured to store one of a plurality of memory states, the plurality of memory states correspond to a group of read voltages, and a read voltage of the group of read voltages is configured to distinguish different memory states, the controller is configured to: perform a read operation on a selected memory cell in a selected block based on the read voltage of the group of read voltages when the memory system is re-powered on after power off; and determine an equivalent power off duration of the memory system according to a read result and a preset mapping table.

In some implementations, the controller is further configured to: obtain an initial timestamp of the block when the memory system is re-powered on after power off, where the initial timestamp is configured to indicate an initial equivalent retention duration of the block before power off, and the initial equivalent retention duration is determined based on a temperature and an initial physical retention duration.

In some implementations, the controller is configured to: determine an equivalent retention duration of the selected block according to the read result and the preset mapping table, where the read result includes a number of memory cells having a threshold voltage greater than or equal to the read voltage and a number of memory cells having a threshold voltage less than the read voltage, the preset mapping table includes a mapping relationship between a preset number range and an equivalent retention duration, and the equivalent retention duration is determined based on a temperature and a physical retention duration; and determine the equivalent power off duration of the memory system according to a difference between the equivalent retention duration of the selected block and the initial timestamp of the selected block, where the equivalent power off duration is determined based on a temperature and a physical power off duration.

In some implementations, the controller is further configured to: update the initial timestamp of the block according to the initial timestamp of the block and the equivalent power off duration; and determine the read voltage when the read operation is performed on the block according to the updated timestamp of the block, where the updated timestamp is configured to indicate a sum of the initial equivalent retention duration of the block before power off and the equivalent power off duration.

In some implementations, the controller is configured to: determine an equivalent retention duration interval, in which the block is, according to the updated timestamp of the block; and determine the read voltage when the read operation is performed on the block according to the equivalent retention duration interval, in which the block is.

In some implementations, the controller is further configured to: if the updated timestamp of the block is greater than or equal to the equivalent retention duration threshold, perform a refresh operation on the block.

In some implementations, the controller is further configured to: read a plurality of reference samples, and determine a read result of each of the reference samples at different equivalent retention durations; and determine a preset number range at the same equivalent retention duration according to the read results of the plurality of reference samples at the same equivalent retention duration, and determine a mapping relationship between the preset number range and the equivalent retention duration as the preset mapping table.

In some implementations, the plurality of reference samples are in different erase range intervals, and the controller is configured to: determine the preset number range of the reference samples in the different erase range intervals at the same equivalent retention duration according to the read results of the reference samples in the different erase range intervals at the same equivalent retention duration, and determine a mapping relationship between the preset number range of the reference samples in the different erase range intervals and the equivalent retention duration as the preset mapping table, where a number of the erase range intervals and a number of the preset mapping tables are the same.

In some implementations, the controller is configured to: determine an erasing range interval, in which the selected block is, according to erasing count of the selected block; and determine the equivalent retention duration of the selected block according to the read result and the preset mapping table corresponding to the erasing range interval, in which the selected block is.

In some implementations, the controller is further configured to: determine a close block having a minimum initial timestamp as the selected block according to the initial timestamp of the block.

According to a third aspect, an implementation of the present disclosure provides a computer-readable storage medium having a computer program stored thereon, which, when executed, implements an operation method of a memory system according to the first aspect of the present disclosure.

Implementations of the present disclosure provide a memory system and an operation method thereof, and a computer readable storage medium. In the implementations of the present disclosure, a read operation is performed on a selected memory cell based on a read voltage of a group of read voltages, and an equivalent power off duration of the memory system is determined according to a read result and a preset mapping table. In this way, the state information of the memory cell can be quickly obtained by using a single-level read operation, and by combining it with a preset mapping table which is pre-characterized, the equivalent power off duration of the memory system is determined; therefore, it is beneficial to determine the equivalent retention duration of data stored in the block, and it is in turn beneficial to determine the read voltage when the read operation is subsequently performed, thereby satisfying the quality of service requirement for the subsequent one-shot read pass of the memory system.

The above description is only an example implementation of the present disclosure, and is not intended to limit the scope of the present disclosure, and any equivalent structural transformation made by using the present disclosure and the accompanying drawings or any direct/indirect application of the present disclosure to other related technical fields is included within the scope of the present disclosure.

What is claimed is:

1. A method of operating a memory system, the method comprising:
performing a read operation on a selected memory cell in a selected block based on a read voltage of a group of read voltages when the memory system is re-powered on after power off; and
determining an equivalent power off duration of the memory system according to a read result and a preset mapping table, wherein the memory system includes a memory and a controller coupled to the memory, the memory includes a plurality of blocks, each of the blocks includes a plurality of memory cells, each of the memory cells is configured to store one of a plurality of memory states, the plurality of memory states correspond to the group of read voltages, and a read voltage of the group of read voltages is configured to distinguish different memory states.

2. The method according to claim 1, wherein the method further includes:
obtaining an initial timestamp of the block when the memory system is re-powered on after power off, wherein the initial timestamp is configured to indicate an initial equivalent retention duration of the block before power off, and the initial equivalent retention duration is determined based on a temperature and an initial physical retention duration.

3. The method according to claim 2, wherein the determining the equivalent power off duration of the memory system according to the read result and the preset mapping table includes:
determining an equivalent retention duration of the selected block according to the read result and the preset mapping table, wherein the read result includes a number of memory cells having a threshold voltage greater than or equal to the read voltage and a number of memory cells having a threshold voltage less than the read voltage, the preset mapping table includes a mapping relationship between a preset number range and an equivalent retention duration, and the equivalent retention duration is determined based on a temperature and a physical retention duration; and
determining the equivalent power off duration of the memory system according to a difference between the equivalent retention duration of the selected block and the initial timestamp of the selected block, wherein the equivalent power off duration is determined based on a temperature and a physical power off duration.

4. The method according to claim 3, wherein after determining the equivalent power off duration of the memory system according to the read result and the preset mapping table, the method further includes:
updating the initial timestamp of the block according to the initial timestamp of the block and the equivalent power off duration; and
determining the read voltage when the read operation is performed on the block according to the updated timestamp of the block, wherein the updated timestamp is configured to indicate a sum of the initial equivalent retention duration of the block before power off and the equivalent power off duration.

5. The method according to claim 4, wherein the determining the read voltage when the read operation is performed on the block according to the updated timestamp of the block includes:
determining an equivalent retention duration interval, in which the block is, according to the updated timestamp of the block; and
determining the read voltage when the read operation is performed on the block according to the equivalent retention duration interval, in which the block is.

6. The method according to claim 4, further including:
if the updated timestamp of the block is greater than or equal to an equivalent retention duration threshold, performing a refresh operation on the block.

7. The method according to claim 3, further including:
reading a plurality of reference samples, and determining a read result of each of the reference samples at different equivalent retention durations; and
determining a preset number range at the same equivalent retention duration according to the read results of the plurality of reference samples at the same equivalent retention duration, and determining a mapping relationship between the preset number range and the equivalent retention duration as the preset mapping table.

8. The method according to claim 7, wherein the plurality of reference samples are in different erase range intervals;
the determining the preset number range at the same equivalent retention duration according to the read results of the plurality of reference samples at the same equivalent retention duration, and determining the mapping relationship between the preset number range and the equivalent retention duration as the preset mapping table includes:
determining the preset number range of the reference samples in the different erase range intervals at the same equivalent retention duration according to the read results of the reference samples in the different erase range intervals at the same equivalent retention duration, and determining the mapping relationship between the preset number range of the reference samples in the different erase range intervals and the equivalent retention duration as the preset mapping table, wherein a number of the erase range intervals and a number of the preset mapping tables are the same.

9. The method according to claim 8, wherein the determining the equivalent power off duration of the memory system according to the read result and the preset mapping table includes:
determining the erasing range interval, in which the selected block is, according to erasing count of the selected block; and
determining the equivalent retention duration of the selected block according to the read result and the preset mapping table corresponding to the erasing range interval, in which the selected block is.

10. The method according to claim 2, wherein after obtaining the initial timestamp of the block after the memory system is re-powered on after power off, the method further includes:
determining a close block having a minimum initial timestamp as the selected block according to the initial timestamp of the block.

11. A memory system comprising:
a memory; and
a controller coupled to the memory,
the memory includes a plurality of blocks, each of the blocks includes a plurality of memory cells, each of the memory cells is configured to store one of a plurality of memory states, the plurality of memory states correspond to a group of read voltages, and a read voltage of the group of read voltages is configured to distinguish different memory states,
the controller is configured to:
perform a read operation on a selected memory cell in a selected block based on the read voltage of the group of read voltages when the memory system is re-powered on after power off; and
determine an equivalent power off duration of the memory system according to a read result and a preset mapping table.

12. The memory system according to claim 11, wherein the controller is further configured to:
obtain an initial timestamp of the block when the memory system is re-powered on after power off, wherein the initial timestamp is configured to indicate an initial equivalent retention duration of the block before power off, and the initial equivalent retention duration is determined based on a temperature and an initial physical retention duration.

13. The memory system according to claim 12, wherein the controller is configured to:
determine an equivalent retention duration of the selected block according to the read result and the preset mapping table, wherein the read result includes a number of memory cells having a threshold voltage greater than or equal to the read voltage and a number of memory cells having a threshold voltage less than the read voltage, the preset mapping table includes a mapping relationship between a preset number range and an equivalent retention duration, and the equivalent retention duration is determined based on a temperature and a physical retention duration; and
determine the equivalent power off duration of the memory system according to a difference between the equivalent retention duration of the selected block and the initial timestamp of the selected block, wherein the equivalent power off duration is determined based on a temperature and a physical power off duration.

14. The memory system according to claim 13, wherein the controller is further configured to:
update the initial timestamp of the block according to the initial timestamp of the block and the equivalent power off duration; and
determine the read voltage when the read operation is performed on the block according to the updated timestamp of the block, wherein the updated timestamp is configured to indicate a sum of the initial equivalent retention duration of the block before power off and the equivalent power off duration.

15. The memory system according to claim 14, wherein the controller is configured to:
determine an equivalent retention duration interval, in which the block is, according to the updated timestamp of the block; and
determine the read voltage when the read operation is performed on the block according to the equivalent retention duration interval, in which the block is.

16. The memory system according to claim 14, wherein the controller is further configured to:
if the updated timestamp of the block is greater than or equal to an equivalent retention duration threshold, perform a refresh operation on the block.

17. The memory system according to claim 13, wherein the controller is further configured to:
read a plurality of reference samples, and determine a read result of each of the reference samples at different equivalent retention durations; and
determine a preset number range at the same equivalent retention duration according to the read results of the plurality of reference samples at the same equivalent retention duration, and determine a mapping relationship between the preset number range and the equivalent retention duration as the preset mapping table.

18. The memory system according to claim 17, wherein the plurality of reference samples are in different erase range intervals, and the controller is configured to:
determine the preset number range of the reference samples in the different erase range intervals at the same equivalent retention duration according to the read results of the reference samples in the different erase range intervals at the same equivalent retention duration, and determine the mapping relationship between the preset number range of the reference samples in the different erase range intervals and the equivalent retention duration as the preset mapping table, wherein a number of the erase range intervals and a number of the preset mapping tables are the same.

19. The memory system according to claim 18, wherein the controller is configured to:
determine an erasing range interval, in which the selected block is, according to erasing count of the selected block; and
determine the equivalent retention duration of the selected block according to the read result and the preset mapping table corresponding to the erasing range interval, in which the selected block is.

20. A computer-readable storage medium having a computer program stored thereon, which, when executed, implements an operation method of a memory system, the operation method comprising:
performing a read operation on a selected memory cell in a selected block based on a read voltage of a group of read voltages when the memory system is re-powered on after power off; and
determining an equivalent power off duration of the memory system according to a read result and a preset mapping table,
wherein the memory system comprises a memory and a controller coupled to the memory, the memory comprises a plurality of blocks, each of the blocks comprises a plurality of memory cells, each of the memory cells is configured to store one of a plurality of memory states, the plurality of memory states correspond to the group of read voltages, and a read voltage of the group of read voltages is configured to distinguish different memory state.
